(19) United States
(12) Patent Application Publication
(10) Pub. No.: US 2026/0013361 A1
(43) Pub. Date: Jan. 8, 2026

(54) DISPLAY DEVICE AND ELECTRONIC DEVICE INCLUDING THE SAME

(71) Applicant: Samsung Display Co., Ltd., Yongin-Si (KR)

(72) Inventors: Gi Na YOO, Yongin-si (KR); Seung Han KIM, Yongin-si (KR); Hyo Min KIM, Yongin-si (KR); Bum Kyun CHOI, Yongin-si (KR)

(21) Appl. No.: 19/056,746

(22) Filed: Feb. 19, 2025

(30) Foreign Application Priority Data
Jul. 3, 2024 (KR) 10-2024-0087358

(51) Int. Cl. H10K 59/38; H10H 29/34; H10H 29/85; H10K 59/126; H10K 59/40

(52) U.S. Cl. CPC H10K 59/38; H10H 29/345; H10H 29/8517; H10K 59/126; H10K 59/40

(57) ABSTRACT

A display device according to an embodiment includes a display device including a display area that includes emission areas and a non-emission area, a light emitting element layer, a color filter layer including color filters arranged in the emission areas, a first light blocking layer disposed in the non-emission area, a first pattern disposed between the light emitting element layer and the color filter layer and disposed under at least one color filter of the first pixel, and a second light blocking layer disposed on the color filter layer and surrounding the emission areas of the second pixel. The at least one color filter of the first pixel includes a central portion that is disposed on the first pattern and protrudes in a height direction, and an edge portion that surrounds the central portion and has a lower height than the central portion.

### CROSS-REFERENCE TO RELATED APPLICATION

This application claims priority to Korean Patent Application No. 10-2024-0087358 filed on Jul. 3, 2024, in the Korean Intellectual Property Office, and all the benefits accruing therefrom under 35 U.S.C. 119, the contents of which in its entirety are incorporated herein by reference.

### BACKGROUND

### 1. Technical Field

Embodiments of the present disclosure relate to a display device and an electronic device including the same.

### 2. Description of the Related Art

With the advance of information-oriented society, more and more demands are placed on display devices for displaying images in various ways. Along with this trend, various types of display devices including a light emitting display device are being developed.

### SUMMARY

Aspects of the present disclosure provide a display device capable of altering a viewing angle according to emission modes and improving viewing angle color shift, and an electronic device including the display device.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device including, a display area including emission areas and a non-emission area surrounding the emission areas, the emission areas including emission areas of a first pixel and emission areas of a second pixel, a light emitting element layer including light emitting elements arranged in the emission areas, a color filter layer disposed on the light emitting element layer, and including color filters respectively arranged in the emission areas and a first light blocking layer disposed in the non-emission area on the light emitting element layer, a first pattern disposed between the light emitting element layer and the color filter layer, and disposed under at least one color filter of the first pixel, and a second light blocking layer disposed on the color filter layer, and surrounding the emission areas of the second pixel. The at least one color filter of the first pixel includes a central portion that is disposed on the first pattern and protrudes in a height direction, and an edge portion that surrounds the central portion and has a lower height than the central portion.

In an embodiment, the emission areas of the first pixel may include a first emission area emitting light of a first color, a second emission area emitting light of a second color, and a third emission area emitting light of a third color.

In an embodiment, the light of the first color, the light of the second color and the light of the third color may be red light, green light and blue light, respectively.

In an embodiment, the first pattern may be disposed in at least the second emission area.

In an embodiment, a size of the second emission area may be smaller than a size of each of the first emission area and the third emission area.

In an embodiment, the first pattern may be disposed in at least the second emission area.

In an embodiment, the first pattern may be individually disposed in each of the first emission area, the second emission area, and the third emission area.

In an embodiment, the first pattern may be disposed in at least two of the first emission area, the second emission area, and the third emission area.

In an embodiment, a color filter disposed in an emission area where the first pattern is not disposed am may include a central portion disposed in the emission area where the first pattern is not disposed, and an edge portion surrounding the central portion and having a height higher than that of the central portion.

In an embodiment, the first pattern may be formed as a light transmitting pattern.

In an embodiment, the display device may further include a touch electrode disposed between the light emitting element layer and the color filter layer.

In an embodiment, the display device may further include an insulating layer covering the touch electrode or disposed under the touch electrode and formed integral with the first pattern, and the insulating layer partially may protrude from a first pixel area to form the first pattern.

In an embodiment, the display device may further include a second pattern disposed between the light emitting element layer and the color filter layer, and disposed under at least one color filter in the non-emission area surrounding an emission area of the second pixel.

In an embodiment, the at least one color filter disposed on the second pattern may have a higher height at an edge portion disposed on the second pattern than at a central portion disposed in a corresponding emission area.

In an embodiment, the second pattern may be disposed under the first light blocking layer and may overlap the first light blocking layer.

In an embodiment, the second pattern and the first light blocking layer may be integral with each other.

In an embodiment, the second pattern may be disposed only in the non-emission area of the second pixel and may be not disposed in the emission areas of the second pixel.

In an embodiment, the second pattern may be disposed entirely in a second pixel area including the emission areas of the second pixel and the non-emission area of the second pixel.

In an embodiment, the display device may further include a touch electrode disposed between the light emitting element layer and the color filter layer, and an insulating layer covering the touch electrode or disposed under the touch electrode and integral with the second pattern.

In an embodiment, the central portions of the color filters that transmit light of the same color among the color filters arranged on the light emitting elements of the first pixel and the color filters arranged on the light emitting elements of the second pixel may have the same thickness.

According to an aspect of the present disclosure, there is provided an electronic device including a display device, the display device including a display area including emission areas and a non-emission area surrounding the emission areas, the emission area including emission areas of a first pixel and emission areas of a second pixel, a light emitting element layer including light emitting elements arranged in the emission areas, a color filter layer disposed on the light emitting element layer and including color filters respectively arranged in the emission areas, a first light blocking layer disposed in the non-emission area, a first pattern disposed between the light emitting element layer and the color filter layer, and disposed under at least one color filter of the first pixel, and a second light blocking layer disposed on the color filter layer, and surrounding emission areas of the second pixel. The at least one color filter of the first pixel may include a central portion that be disposed on the first pattern and may protrude in a height direction, and an edge portion that surrounds the central portion and has a lower height than the central portion.

According to embodiments, by utilizing a first pixel and a second pixel, the viewing angle of the display device may be appropriately or easily altered according to respective emission modes.

Further, according to embodiments, the viewing angle color shift may be improved by differentially and/or selectively disposing at least one of a first pattern or a second pattern under color filters of the first pixel and the second pixel.

In accordance with some embodiments, by disposing the first pattern under the color filter in at least one emission area among the emission areas of the first pixel, the color filter may be formed to have a higher height at a central portion and an overall convex shape. Accordingly, the side luminance and/or side color of the first pixel may be adjusted or improved.

According to some embodiments, by disposing the second pattern under at least color filter among the color filters of the second pixel in a non-emission area around the emission areas of the second pixel, the at least one color filter may be formed to have a higher height at an edge portion located in the non-emission area, a larger stepped portion between the central portion located in the emission area and the edge portion located in the non-emission area, and an overall concave shape. Accordingly, the side light blocking rate and/or side color of the second pixel may be adjusted or improved.

However, effects according to the embodiments of the present disclosure are not limited to those exemplified above and various other effects are incorporated herein.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view showing an electronic device according to one embodiment;

FIG. 2 is a perspective view illustrating a display device included in an electronic device according to one embodiment;

FIG. 3 is a cross-sectional view of the display device of FIG. 2 viewed from the side;

FIG. 4 is a plan view illustrating a display area of a display device according to one embodiment;

FIG. 5 is a plan view illustrating pixel electrodes according to one embodiment;

FIG. 6 is a plan view showing pixel electrodes, a first light blocking layer, and color filters according to one embodiment;

FIG. 7 is a plan view showing pixel electrodes and a second light blocking layer according to one embodiment;

FIG. 8 is a plan view illustrating a display area of a display device according to one embodiment;

FIG. 9 is a cross-sectional view illustrating a display device according to one embodiment;

FIG. 10 is a cross-sectional view showing a display device according to one embodiment;

FIG. 11 is a cross-sectional view showing a display device according to one embodiment;

FIG. 12 is a cross-sectional view illustrating a display device according to one embodiment;

FIG. 13 is a cross-sectional view showing a display device according to one embodiment;

FIG. 14 is a cross-sectional view illustrating a display device according to one embodiment;

FIG. 15 is a cross-sectional view illustrating a display device according to one embodiment;

FIG. 16 is a cross-sectional view showing a display device according to one embodiment;

FIG. 17 is a cross-sectional view showing a display device according to one embodiment;

FIG. 18 is a cross-sectional view showing a display device according to one embodiment;

FIG. 19 is a cross-sectional view illustrating a display device according to one embodiment; and

FIG. 20 is a cross-sectional view showing a display device according to one embodiment.

### DETAILED DESCRIPTION OF THE EMBODIMENTS

The present inventive concept will now be described more fully hereinafter with reference to the accompanying drawings, in which preferred embodiments of the inventive concept are shown. This inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art.

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present inventive concept. Similarly, the second element could also be termed the first element.

Features of each of various embodiments of the present disclosure may be partially or entirely combined with each other and may technically variously interwork with each other, and respective embodiments may be implemented independently of each other or may be implemented together in association with each other.

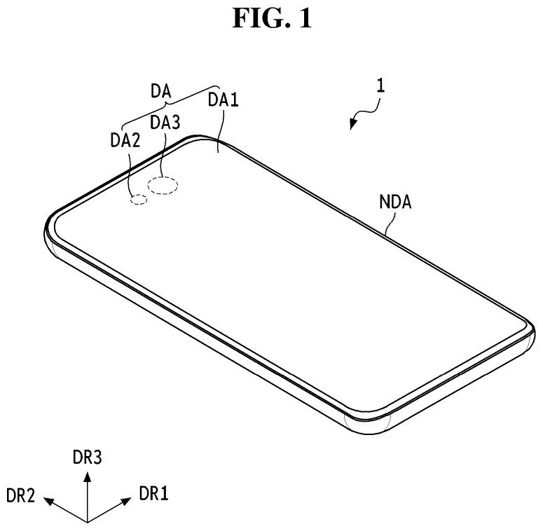

FIG. 1 is a perspective view showing an electronic device according to one embodiment.

Referring to FIG. 1, an electronic device 1 displays a moving image or a still image. The electronic device 1 may refer to any electronic device providing a display screen. Examples of the electronic device 1 may include a television, a laptop computer, a monitor, a billboard, an Internet-of-Things device, a mobile phone, a smartphone, a tablet personal computer (PC), an electronic watch, a smart watch, a watch phone, a head-mounted display, a mobile communication terminal, an electronic notebook, an electronic book, a portable multimedia player (PMP), a navigation device, a game machine, a digital camera, a camcorder and the like, which provide a display screen.

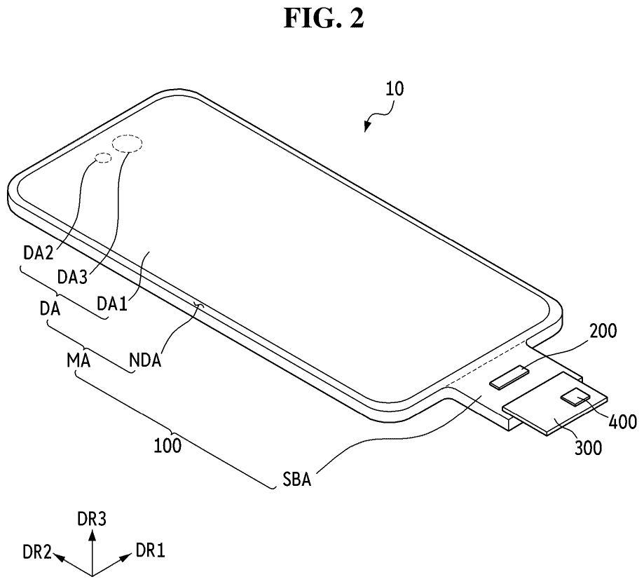

The electronic device 1 may include a display device (e.g., a display device 10 of FIG. 2) providing a display screen. In one embodiment, the display device may be a light emitting display device including a light emitting element such as an inorganic light emitting diode or an organic light emitting diode, but the configuration of the display device is not limited thereto. For example, although a light emitting display device including an organic light emitting diode is described as a display device to which embodiments may be applied, devices or fields to which embodiments may be applied are not limited thereto. For example, embodiments may also be applied to other types of display devices.

The shape of the electronic device 1 may be variously modified. For example, the electronic device 1 may have a shape such as a rectangular shape elongated in a horizontal direction, a rectangular shape elongated in a vertical direction, a square shape, a substantially quadrilateral shape with rounded corners, other polygonal shapes and a circular shape. In one embodiment, the shape of a display area DA of the electronic device 1 may be similar to the overall shape of the electronic device 1, but is not limited thereto. In FIG. 1, the electronic device 1 having a rectangular shape that is longer in a second direction DR2 than in a first direction DR1 is exemplified.

The electronic device 1 may include the display area DA and a non-display area NDA. The display area DA is an area where an image can be displayed, and the non-display area NDA is an area where an image is not displayed. The display area DA may also be referred to as an active region, and the non-display area NDA may also be referred to as a non-active region. The display area DA may substantially occupy the center of the electronic device 1.

The display area DA may include a first display area DA1, a second display area DA2, and a third display area DA3. The second display area DA2 and the third display area DA3 are areas in which components for executing various functions to the electronic device 1 are disposed, and the second display area DA2 and the third display area DA3 may correspond to a component area. Although FIG. 1 shows an embodiment in which the electronic device 1 includes two component areas, the number or location of the component areas is not limited. The first display area DAI may be an area of the display area DA where no component is disposed.

FIG. 2 is a perspective view illustrating a display device included in an electronic device according to one embodiment.

Referring to FIGS. 1 and 2, the electronic device 1 according to one embodiment may include the display device 10. The display device 10 may provide a screen of the electronic device 1. The display device 10 may have a planar shape similar to the shape of the electronic device 1. For example, the display device 10 may have a shape similar to a rectangular shape having a short side in the first direction DR1 and a long side in the second direction DR2. The edge where the short side in the first direction DR1 and the long side in the second direction DR2 meet may be rounded, but is not limited thereto and may be formed at a right angle. The planar shape of the display device 10 is not limited to a quadrilateral shape, and may have another polygonal shape, a circular shape, an elliptical shape, or another shape.

The display device 10 may include a display panel 100, a display driver 200, a circuit board 300, and a touch driver 400.

The display panel 100 may include a main region MA and a sub-region SBA.

The main region MA may include the display area DA including pixels displaying an image and the non-display area NDA disposed around the display area DA. The display area DA may be disposed in the center of the main region MA, and the non-display area NDA may surround the display area DA.

The display area DA may include the first display area DA1, the second display area DA2, and the third display area DA3. The display area DA may include emission areas of the pixels, and light may be emitted from the emission areas.

The display panel 100 may include light emitting elements and pixel circuits (e.g., pixel circuits including transistors and capacitors) of the pixels, and a pixel defining film surrounding the emission areas of the pixels. The light emitting element of each of the pixels may be disposed in the emission area of the corresponding pixel. In one embodiment, the light emitting element may include one of an organic light emitting diode (LED) including an organic light emitting layer, a quantum dot LED including a quantum dot light emitting layer, an inorganic LED including an inorganic semiconductor, and an ultra-small light emitting diode such as a micro LED or nano LED, but is not limited thereto.

The non-display area NDA may be an area outside the display area DA. The non-display area NDA may be defined as an edge area of the main region MA of the display panel 100. In one embodiment, the non-display area NDA may include a gate driver (not illustrated) that supplies gate signals to the gate lines, and fan-out lines (not illustrated) that connect the display driver 200 to data lines disposed in the display area DA.

The sub-region SBA may be a region extending from one side of the main region MA. The sub-region SBA may include a flexible material which can be bent, folded or rolled. For example, when the sub-region SBA is bent (or folded), the sub-region SBA may overlap the main region MA in a thickness direction (e.g., a third direction DR3). For example, when the display device 10 is bent in the sub-region SBA, at least a part of the sub-region SBA including an area where the display driver 200 is disposed and an area where a pad portion connected to the circuit board 300 is disposed may be disposed under the main region MA.

The sub-region SBA may include the display driver 200 and a pad portion connected to the circuit board 300. In another embodiment, the sub-region SBA may be omitted, and the display driver 200 and the pad portion may be disposed in the non-display area NDA. In another embodiment, the display driver 200 may be disposed on the circuit board 300 connected to the display panel 100, and may be electrically connected to the display panel 100 through the pad portion.

The display driver 200 may output driving signals and driving voltages for driving the display panel 100. For example, the display driver 200 may supply data voltages to data lines, supply driving voltages (e.g., first pixel voltage or anode voltage) and second pixel voltage (or cathode voltage)) to power lines, and supply gate control signals to the gate driver. In one embodiment, the display driver 200 may be formed as an integrated circuit (IC) and mounted on the display panel 100 by a chip on glass (COG) method, a chip on plastic (COP) method, or an ultrasonic bonding method.

The circuit board 300 may be attached to the pad portion of the display panel 100 by using an anisotropic conductive film (ACF) or the like. Lead lines of the circuit board 300 may be electrically connected to the pad portion of the display panel 100. In one embodiment, the circuit board 300 may be a flexible printed circuit board, a printed circuit board, or a flexible film such as a chip on film.

The touch driver 400 may be mounted on the circuit board 300. The touch driver 400 may be connected to a touch sensing layer of the display panel 100. The touch driver 400 may supply each touch drive signal to touch electrodes of the touch sensing layer, and may sense the amount of change in capacitance formed between the touch electrodes. In one embodiment, the touch driving signal may be a pulse signal having a predetermined frequency. The touch driver 400 may detect whether or not a touch input has occurred and coordinates based on the amount of change in capacitance between the touch electrodes. In one embodiment, the touch driver 400 may be formed as an integrated circuit (IC).

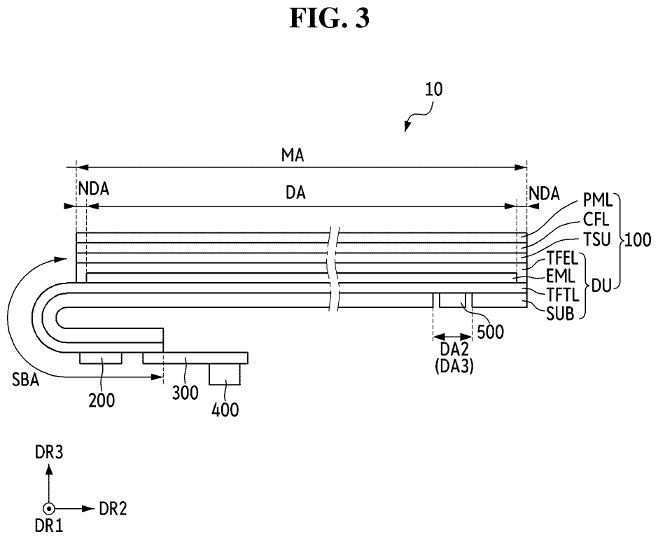

FIG. 3 is a cross-sectional view of the display device of FIG. 2 viewed from the side. FIG. 3 illustrates the sub-region SBA of the display panel 100 in a bent state in the display device 10 of FIG. 2.

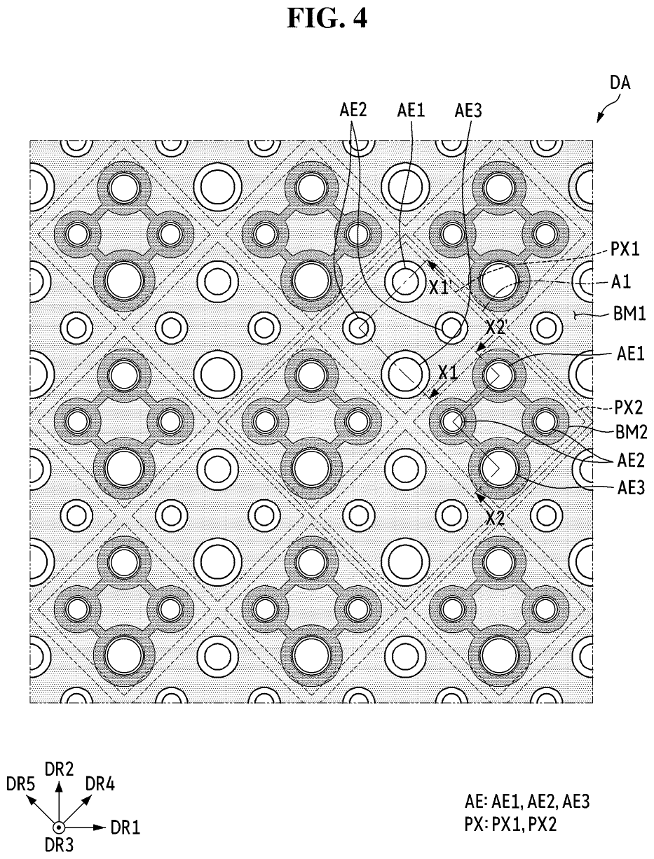

Referring to FIG. 3, the display panel 100 may include a display layer DU, a touch sensing layer TSU, a color filter layer CFL, and a light blocking member layer PML. Although the color filter layer CFL and the light blocking member layer PML are separately illustrated in FIG. 3, embodiments are not limited thereto. For example, an element (e.g., a second light blocking layer BM2 of FIG. 4) included in the light blocking member layer PML, which is an element disposed in the color filter layer CFL, may be considered as an element disposed at a higher portion among the elements of the color filter layer CFL.

The display layer DU may include a substrate SUB, a thin film transistor layer TFTL, a light emitting element layer EML, and an encapsulation layer TFEL.

The substrate SUB may be a base substrate or a base member. The substrate SUB may be a flexible substrate which can be bent, folded or rolled, but is not limited thereto. In one embodiment, the substrate SUB may include a polymer resin such as polyimide (PI). In another embodiment, the substrate SUB may include a glass material or a metal material. The thin film transistor layer TFTL may be disposed on the substrate SUB. The thin

film transistor layer TFTL may include circuit elements, e.g., thin film transistors and capacitors, constituting pixel circuits of pixels. The thin film transistor layer TFTL may further include wires. For example, the thin film transistor layer TFTL may further include gate lines, data lines, power lines, gate control lines, fan-out lines that connect the display driver 200 to the data lines, and lead lines that connect the display driver 200 to the pad portion. Each of the thin film transistors may include a semiconductor region, a source electrode, a drain electrode, and a gate electrode. In one embodiment, when the display panel 100 includes the gate driver disposed in the non-display area NDA, the thin film transistor layer TFTL may further include circuit elements constituting the gate driver.

The thin film transistor layer TFTL may be disposed in the display area DA, the non-display area NDA, and the sub-region SBA. The circuit elements constituting the pixel circuits of the pixels, and the gate lines, the data lines, and the power lines that are electrically connected to the pixels may be disposed in the display area DA of the thin film transistor layer TFTL. The gate lines, the data lines, and the power lines may extend to the non-display area NDA of the thin film transistor layer TFTL, and may be respectively electrically connected to the gate driver, the display driver 200, or the pad portion. The gate control lines and the fan-out lines may be disposed in the non-display area NDA of the thin film transistor layer TFTL. The lead lines may be disposed in the sub-region SBA of the thin film transistor layer TFTL.

The light emitting element layer EML may be disposed on the thin film transistor layer TFTL. The light emitting element layer EML may include a pixel defining film that defines emission areas (or light emitting element arrangement areas) of pixels, and light emitting elements arranged in the emission areas. Each emission area may be disposed in each pixel area of the display area DA. For example, the pixel area where the respective pixels of the display area DA are disposed may include a pixel circuit area where circuit elements constituting the pixel circuit of the corresponding pixel are disposed and an emission area where the light emitting element of the corresponding pixel is disposed. In one embodiment, the emission area and the pixel circuit area of each pixel may overlap each other in the third direction DR3.

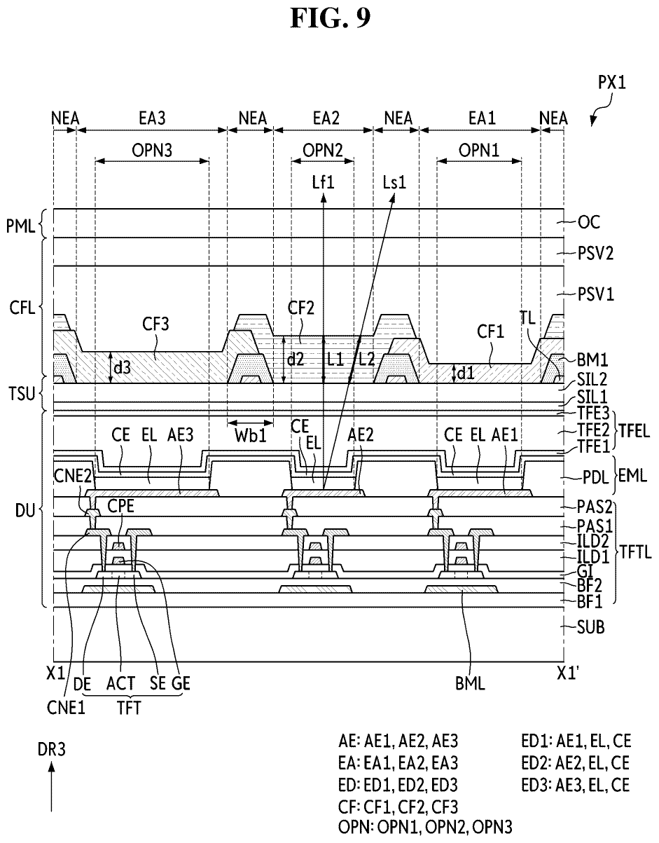

The light emitting element may include a first electrode and a second electrode facing each other, and a light emitting layer interposed between the first electrode and the second electrode. In one embodiment, the first electrode of the light emitting element may correspond to the pixel electrode shown in FIG. 4 and subsequent drawings, and the second electrode of the light emitting element may correspond to the common electrode shown in FIG. 9 and subsequent drawings. In one embodiment, the light emitting layer may be an organic light emitting layer including an organic material. The light emitting layer may include a hole transporting layer, an organic light emitting layer, and an electron transporting layer. When a first pixel voltage (e.g., anode voltage) is applied to the first electrode of the light emitting element through at least one of the thin film transistors of each pixel circuit, and a second pixel voltage (e.g., cathode voltage) is applied to the second electrode of the light emitting element through the power line, holes and electrons may recombine in an organic light emitting layer and the light emitting element may emit light. In another embodiment, the light emitting element may be another type of light emitting element, such as a quantum dot light emitting diode including a quantum dot light emitting layer, an inorganic light emitting diode including an inorganic semiconductor, a micro light emitting diode, or a nano light emitting diode.

The encapsulation layer TFEL may cover the top surface and the side surface of the light emitting element layer EML, and may protect the light emitting element layer EML. In one embodiment, the encapsulation layer TFEL may include at least one inorganic layer and at least one organic layer for encapsulating the light emitting element layer EML. For example, the encapsulation layer TFEL may include a plurality of inorganic encapsulation layers and an organic encapsulation layer interposed between the inorganic encapsulation layers.

The touch sensing layer TSU may be disposed on the display layer DU. For example, the touch sensing layer TSU may be disposed or formed on the encapsulation layer TFEL, or the touch sensing layer TSU may be disposed on a separate substrate and attached to the display layer DU using an adhesive layer.

The touch sensing layer TSU may include touch electrodes for sensing the user's touch input, and wires that electrically connect the touch electrodes to the touch driver 400. In one embodiment, the touch sensing layer TSU may sense the user's touch in a mutual capacitance manner or a self-capacitance manner, and the touch electrodes may have a shape for constituting a mutual capacitance type or self-capacitance type touch sensor. For example, the touch electrodes may include driving electrodes and sensing electrodes extending and/or connected in different directions to constitute a mutual capacitance type touch sensor, or may include touch electrodes disposed at points corresponding to respective touch nodes or coordinates to constitute a self-capacitance type touch sensor.

The touch electrodes of the touch sensing layer TSU may be disposed in a touch sensor area overlapping the display area DA. The area in the display area DA where the touch electrodes are disposed may be the touch sensor area. For example, the touch sensor area may be all or a part of the display area DA. Wires electrically connected to the touch electrodes of the touch sensing layer TSU may be disposed in a peripheral area overlapping the non-display area NDA.

The color filter layer CFL may be disposed on the touch sensing layer TSU. The color filter layer CFL may include color filters disposed in areas corresponding to the respective emission areas of the pixels. Each of the color filters may selectively transmit light of a specific color or wavelength and may block or absorb light of a different color or wavelength. In one embodiment, the color filter layer CFL may further include a first light blocking layer (or first light blocking patterns forming the first light blocking layer) surrounding the emission areas of the pixels. The first light blocking layer may be formed separately from the color filters by using a separate light blocking material, or may be formed by overlapping a plurality of color filters that selectively transmit light of different wavelengths.

The color filter layer CFL may absorb a part of light coming from the outside of the display device 10 to reduce reflected light due to external light. Color distortion caused by reflection of the external light may be prevented by the color filter layer CFL.

In one embodiment, the color filter layer CFL may be disposed directly on the touch sensing layer TSU. Accordingly, the display device 10 may not include a separate substrate for the color filter layer CFL, and may have a further reduced thickness.

The light blocking member layer PML may be disposed on the color filter layer CFL. The light blocking member layer PML may include a second light blocking layer (or second light blocking patterns forming the second light blocking layer) disposed to correspond to specific pixels of the display layer DU. For example, the light blocking member layer PML may include the second light blocking layer that is disposed adjacent to the emission areas of specific pixels and surrounds the emission areas in a plan view.

The light blocking member layer PML may limit the viewing angle of the image displayed by the specific pixels. For example, the display device 10 includes the light blocking member layer PML and thus may control visibility at a specific viewing angle and provide a side viewing angle blocking mode, such as a privacy protection mode, to a user.

In some embodiments, the display device 10 may further includes an optical device 500 disposed in a component area (e.g., the second display area DA2 or the third display area DA3 of FIGS. 1 and 2). The optical device 500 may emit or receive light in infrared, ultraviolet, and visible light bands. For example, the optical device 500 may be an optical sensor that detects light incident on the display device 10 such as a proximity sensor, an illuminance sensor, and a camera sensor or an image sensor.

FIG. 4 is a plan view illustrating a display area of a display device according to one embodiment. For example, FIG. 4 shows pixel electrodes AE disposed in the display area DA of the display device 10 according to one embodiment and a first light blocking layer BM1 and a second light blocking layer BM2 disposed around the pixel electrodes AE.

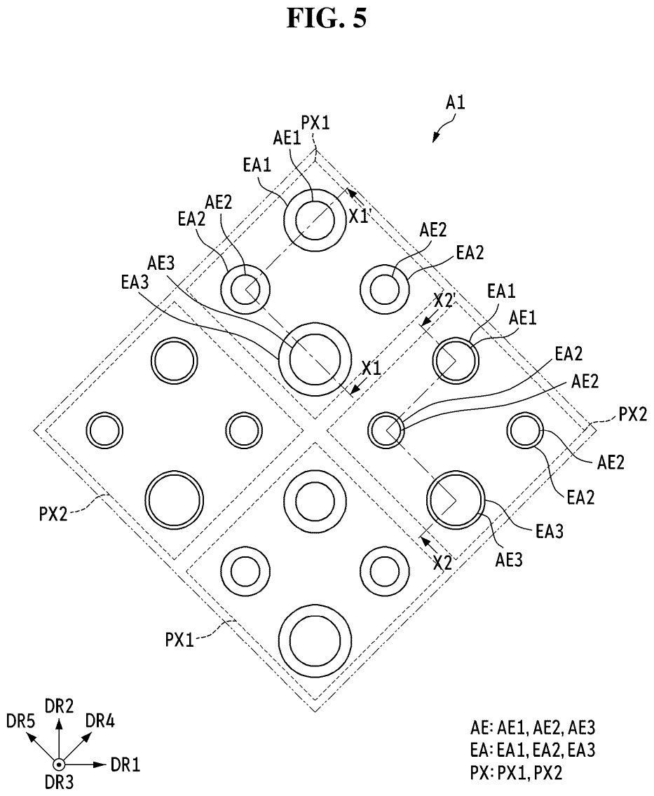

FIG. 5 is a plan view illustrating pixel electrodes according to one embodiment. For example, FIG. 5 shows the pixel electrodes AE disposed in area A1 of FIG. 4 and the emission areas EA where the pixel electrodes AE are disposed.

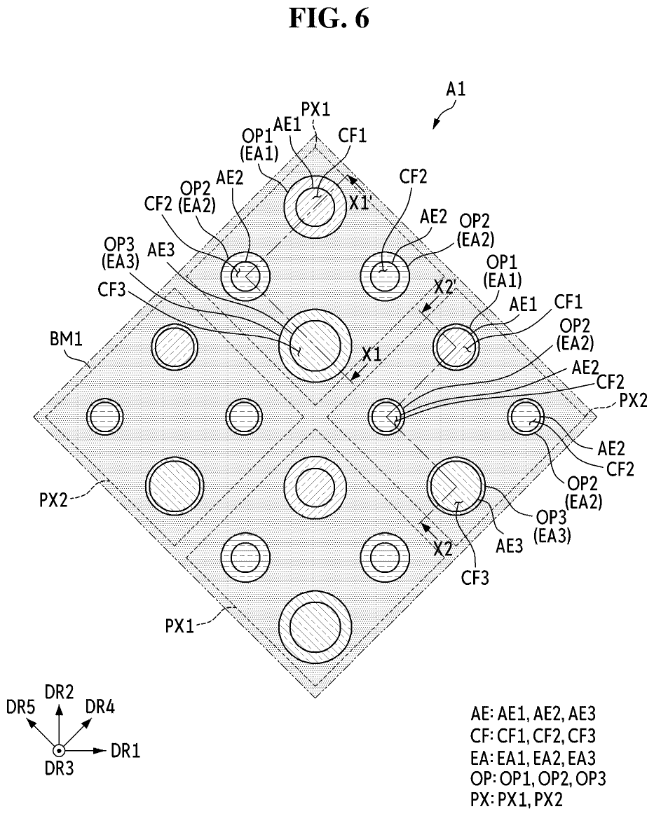

FIG. 6 is a plan view showing pixel electrodes, a first light blocking layer, and color filters according to one embodiment. For example, FIG. 6 shows the pixel electrodes AE disposed in area A1 of FIG. 4 and the first light blocking layer BM1 and the color filters CF disposed around the pixel electrodes AE.

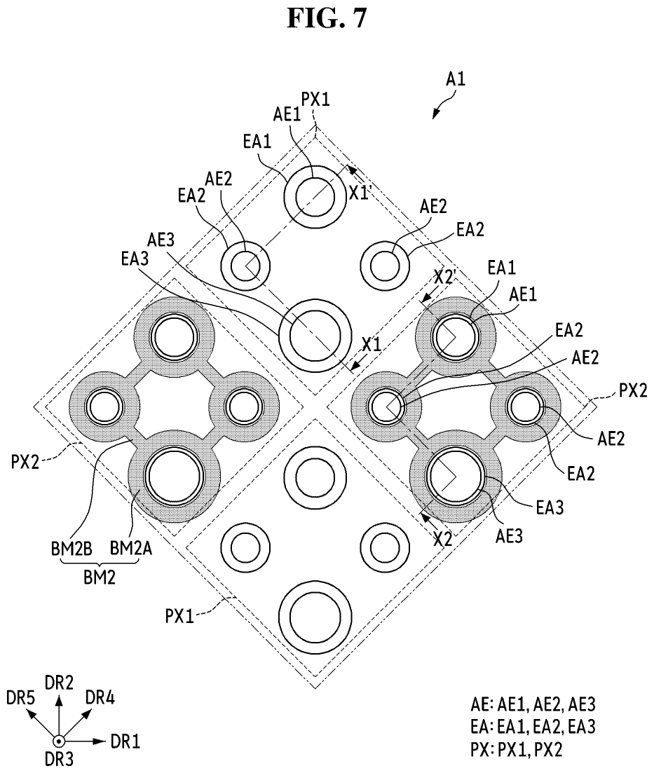

FIG. 7 is a plan view showing pixel electrodes and a second light blocking layer according to one embodiment. For example, FIG. 7 shows the pixel electrodes AE disposed in area A1 of FIG. 4 and the second light blocking layer BM2 disposed around the pixel electrodes AE.

Referring to FIGS. 4 to 7, the display device 10 may include the pixels PX disposed in the display area DA. In one embodiment, the pixels PX may be arranged in a fourth direction DR4 and a fifth direction DR5 between the first direction DR1 and the second direction DR2. In one embodiment, the fourth direction DR4 and the fifth direction DR5 may be diagonal directions with respect to the first direction DR1 and the second direction DR2.

The display area DA may include the emission areas EA of the pixels PX and the non-emission area surrounding the emission areas EA. In describing the embodiments, the non-emission area may refer to the remaining area of the display area DA excluding the emission areas EA. For example, the non-emission area, which is an area disposed around the respective emission areas EA and between the emission areas EA, may be an area where the first light blocking layer BM1 of FIGS. 4 and 6 is disposed. The pixel area where each pixel PX is disposed may include the emission areas EA of the corresponding pixel PX and the non-emission area disposed directly around the emission areas EA.

In one embodiment, each of the pixels PX may include a plurality of pixel electrodes AE. For example, each of the pixels PX may include a first pixel electrode AE1, a second pixel electrode AE2, and a third pixel electrode AE3. In one embodiment, one pixel PX may include one first pixel electrode AE1, two second pixel electrodes AE2, and one third pixel electrode AE3. However, embodiments are not limited thereto, and the number of pixel electrodes AE disposed in the pixel PX may be variously changed.

One pixel electrode AE may be a first electrode, e.g., an anode electrode, of a light emitting element included in each pixel PX. In one embodiment, one pixel PX may include a plurality of light emitting elements and a plurality of pixel circuits electrically connected to the plurality of light emitting elements, respectively. Each pixel circuit may be electrically connected to at least one light emitting element. Each pixel circuit and at least one light emitting element connected to the pixel circuit may constitute each sub-pixel.

Each pixel electrode AE shown in FIGS. 4 to 7 may be the entire pixel electrode AE, or a part of the pixel electrode AE exposed in an area where the pixel defining film is opened. For example, each pixel electrode AE illustrated in FIGS. 4 to 7 may have a size and/or shape corresponding to the opening of the pixel defining film corresponding to each emission area EA. On each pixel electrode AE, the light emitting layer of the light emitting element and the second electrode (e.g., common electrode) may be disposed.

In one embodiment, one pixel PX may include a plurality of light emitting elements that emit light of different colors. For example, the light emitting element (e.g., first light emitting element) including the first pixel electrode AE1 may emit light of a first color (e.g., red light). The light emitting element (e.g., second light emitting element) including the second pixel electrode AE2 may emit light of a second color (e.g., green light), and the light emitting element (e.g., third light emitting element) including the third pixel electrode AE3 may emit light of a third color (e.g., blue light). Accordingly, the pixel PX may emit any one of the first color light, the second color light, and the third color light, or may emit a mixture of at least two of the first color light, the second color light, and the third color light.

For example, all the light emitting elements included in one pixel PX emit light, so that white light may be emitted from the pixel PX. However, the type, number, and arrangement the pixel electrodes AE constituting one pixel PX and the light emitting elements including the same may be variously changed depending on embodiments.

As shown in FIG. 5, the pixel electrodes AE may be disposed in the emission areas EA of each pixel PX. Each pixel PX may include the plurality of emission areas EA including a first emission area EA1 that emits light of the first color, a second emission area EA2 that emits light of the second color, and a third emission area EA3 that emits light of the third color. In one embodiment, one pixel PX may include one first emission area EA1, two second emission areas EA2, and one third emission area EA3, but embodiments are not limited thereto. The first pixel electrode AE1 may be disposed in the first emission area EA1, the second pixel electrode AE2 may be disposed in the second emission area EA2, and the third pixel electrode AE3 may be disposed in the third emission area EA3. The light emitting element including each pixel electrode AE may be disposed in each emission area EA.

In one embodiment, each emission area EA may include an area where each pixel electrode AE is exposed by an opening formed in the pixel defining film. For example, each emission area EA may be primarily defined by the pixel defining film. Further, each emission area EA, which is an area that is not blocked by the first light blocking layer BM1 and the second light blocking layer BM2, may be a light transmitting area through which light generated from the light emitting element including each pixel electrode AE transmits. For example, each emission area EA may correspond to an opening OP of the first light blocking layer BM1.

In describing the embodiments of FIGS. 4 to 7, the areas where the light emitting elements are exposed by the openings OP of the first light blocking layer BM1 are defined as the emission areas EA, and the light blocking area where the first light blocking layer BM1 is disposed is defined as the non-emission area, but the criteria for distinguishing the emission areas EA from the non-emission area may vary. For example, the areas where the pixel electrodes AE are exposed by the openings of the pixel defining film may be defined as the emission areas EA.

In one embodiment, the pixel electrodes AE may be arranged to have a Pentile™ configuration, e.g., a diamond Pentile™ configuration. For example, the first pixel electrodes AE1 and the third pixel electrodes AE3 may be spaced apart from each other in the second direction DR2, and may be arranged alternately in the first direction DR1 and the second direction DR2. In each pixel PX, the first pixel electrode AEl and the third pixel electrode AE3 may be spaced apart from each other in the second direction DR2, and the first pixel electrode AE1 and the third pixel electrode AE3 may be spaced apart from the second pixel electrodes AE2 in the fourth direction DR4 or the fifth direction DR5. The second pixel electrodes AE2 may be repeatedly arranged along the first direction DR1 and the second direction DR2. The second pixel electrodes AE2 and the first pixel electrodes AE1, or the second pixel electrodes AE2 and the third pixel electrodes AE3 may be arranged alternately along the fourth direction DR4 or the fifth direction DR5. However, embodiments are not limited thereto, and the arrangement of the pixel electrodes AE may be variously changed.

In one embodiment, the sizes (e.g., areas) of the first pixel electrode AE1, the second pixel electrode AE2, and the third pixel electrode AE3 may be different from each other. For example, the area of the third pixel electrode AE3 may be larger than those of the first pixel electrode AE1 and the second pixel electrode AE2, and the area of the first pixel electrode AE1 may be larger than that of the second pixel electrode AE2. The intensity of light emitted from each emission area EA may vary depending on the area of the emission area EA where each pixel electrode AE is disposed. Accordingly, the color of the screen displayed on the display device 10 or the electronic device 1 may be controlled by adjusting the area of each pixel electrode AE and the emission area EA including the same. Although FIGS. 4 to 7 show an embodiment in which the third pixel electrode AE3 has the largest area, embodiments are not limited thereto. For example, the size (e.g., area) of the pixel electrode AE and the emission area EA including the same may be freely adjusted depending on the color of the screen required for the display device 10 or the electronic device 1. In addition, the areas of the pixel electrode AE and the emission area EA may be related to light efficiency, the lifespan of the light emitting element ED, or the like, and may have a trade-off relation with the reflection by external light. The area of the pixel electrodes AE may be appropriately adjusted in consideration of the above factors.

In one embodiment, the sizes of the pixel electrodes AE of the pixels PX may be uniform. For example, the sizes (or the aperture ratio of the pixel defining film or the sizes of the openings of the pixel defining film exposing the first pixel electrode AE1, the second pixel electrode AE2, and the third pixel electrode AE3 of the first pixel PX1) of the first pixel electrode AE1, the second pixel electrode AE2, and the third pixel electrode AE3 of the first pixel PX1 may be substantially the same as the sizes (or the aperture ratio of the pixel defining film or the sizes of the openings of the pixel defining film exposing the first pixel electrode AE1, the second pixel electrode AE2, and the third pixel electrode AE3 of the second pixel PX2) of the first pixel electrode AE1, the second pixel electrode AE2, and the third pixel electrode AE3 of the second pixel PX2.

In one embodiment, the sizes (e.g., areas) of the first pixel electrode AE1, the second pixel electrode AE2, and the third pixel electrode AE3 of each pixel PX may be different from each other. For example, the area of the third pixel electrode AE3 may be larger than those of the first pixel electrode AEl and the second pixel electrode AE2, and the area of the first pixel electrode AEl may be larger than that of the second pixel electrode AE2. The intensity of light emitted from each emission area EA may vary depending on the area of the emission area EA where each pixel electrode AE is disposed.

As shown in FIG. 6, the emission areas EA of the pixels PX may be surrounded by the first light blocking layer BM1. Further, the color filters CF may be disposed in the emission areas EA of the pixels PX. The color filters CF may be disposed on the light emitting element layer (e.g., the light emitting element layer EML of FIG. 3) including the light emitting elements of the pixels PX.

The first light blocking layer BM1 may be entirely disposed in the display area DA, and may include the openings OP corresponding to the emission areas EA of the pixels PX. For example, the first light blocking layer BM1 may be disposed in the non-emission area around the emission areas EA, and may include the openings OP exposing the emission areas EA. In a plan view, the first light blocking layer BM1 may include first openings OP1 exposing the first emission areas EA1, second openings OP2 exposing the second emission areas EA2, and third openings OP3 exposing the third emission areas EA3, and may surround the first emission areas EA1, the second emission areas EA2, and the third emission areas EA3. The first light blocking layer BM1 may block the other part (e.g., the non-emission area) of the display area DA except the first emission areas EA1, the second emission areas EA2, and the third emission areas EA3.

The openings OP of the first light blocking layer BM1 may be disposed in areas corresponding to the pixel electrodes AE, or a part of the pixel electrodes AE exposed by the openings of the pixel defining film. The first openings OP1 of the first light blocking layer BM1 may be disposed in areas corresponding to the respective first pixel electrodes AE1. The second openings OP2 of the first light blocking layer BM1 may be disposed in areas corresponding to the respective second pixel electrodes AE2. The third openings OP3 of the first light blocking layer BM1 may be disposed in areas corresponding to the respective third pixel electrodes AE3. In the pixel area where one pixel PX is disposed, one first opening OP1, two second openings OP2, and one third opening OP3 may be formed in the first light blocking layer BM1.

Each of the openings OP of the first light blocking layer BM1 may be greater than each pixel electrode AE (or a part of the pixel electrode AE not covered by the pixel defining film) in a plan view. For example, the area of the first opening OP1 may be larger than the area of the first pixel electrode AE1, the area of the second opening OP2 may be larger than the area of the second pixel electrode AE2, and the area of the third opening OP3 may be larger than the area of the third pixel electrode AE3 in a plan view. In one embodiment, the area of the first opening OP1, the area of the second opening OP2, and the area of the third opening OP3 of the first light blocking layer BM1 may be different from each other. For example, the area of the first opening OP1, the area of the second opening OP2, and the area of the third opening OP3 may respectively correspond to the area of the first pixel electrode AE1, the area of the second pixel electrode AE2, and the area of the third pixel electrode AE3. Further, the sizes (e.g., areas) of the first emission area EA1, the second emission area EA2, and the third emission area EA3 may be different to correspond to the area of the first opening OP1, the area of the second opening OP2, and the area of the third opening OP3 of the first light blocking layer BM1. For example, the size of the second emission area EA2 may be smaller than the size of each of the first emission area EA1 and the third emission area EA3, and the size of the third emission area EA3 may be larger than the size of each of the first emission area EA1 and the second emission area EA2.

The display area DA may include at least two types of pixels PX. For example, the display area DA may include first pixels PX1 and second pixels PX2. The light exit angles and/or viewing angles of the first pixels PX1 and the second pixels PX2 may be different. For example, the first pixels PX1 may be the pixels PX that provide a wider range of light exit angles and/or viewing angles, and the second pixels PX2 may be the pixels PX that provide a narrower range of light exit angles and/or viewing angles.

In one embodiment, the first pixels PX1 may be driven only in a first emission mode, and may be turned off or may not emit light in a second emission mode. The second pixels PX2 may be driven in both the first emission mode and the second emission mode. The first emission mode may be a general mode, e.g., a wide viewing angle mode, in which the viewing angle of the image displayed in the display area DA is not limited, and the second emission mode may be a side viewing angle blocking mode, e.g., a privacy protection mode or a security mode, in which the viewing angle of the image displayed in the display area DA is limited.

In one embodiment, the first pixels PX1 and the second pixels PX2 may be alternately arranged along the fourth direction DR4 and the fifth direction DR5. Further, the first pixels PX1 may be repeatedly arranged along the first direction DR1 and the second direction DR2, and the second pixels PX2 may be repeatedly arranged along the first direction DR1 and the second direction DR2. For example, the first pixels PX1 and the second pixels PX2 may be alternately arranged and uniformly distributed in the entire display area DA. However, embodiments are not limited thereto, and the arrangement shape of the first pixels PX1 and the second pixels PX2 may be variously changed.

In one embodiment, the separation distance between the openings OP of the first light blocking layer BM1 and the pixel electrodes AE (or a difference in a size of the openings OP of the first light blocking layer BM1 and the emission areas EA of the first pixels PX1) in the first pixels PX1 may be different from the separation distance) between the openings OP of the first light blocking layer BM1 and the pixel electrodes AE (or a difference in a size of the openings OP of the first light blocking layer BM1 and the emission areas EA of the second pixels PX2 in the second pixels PX2. For example, in a plan view, the separation distance between the openings OP of the first light blocking layer BM1 and the pixel electrodes AE in the first pixels PX1 (or the difference in the diameters of the openings OP of the first light blocking layer BM1 and the diameters of the pixel electrodes AE in the first pixels PX1) may be greater than the separation distance between the openings OP of the first light blocking layer BM1 and the pixel electrodes AE in the second pixels PX2 (or the difference in the diameters of the openings OP of the first light blocking layer BM1 and the diameters of the pixel electrodes AE in the second pixels PX2). For example, the first light blocking layer BM1 may surround the light emitting elements including the pixel electrodes AE of the second pixels PX2 at a shorter distance than the light emitting elements including the pixel electrodes AE of the first pixels PX1. Further, the size of the openings OP of the first light blocking layer BM1 defining the emission areas EA of the first pixels PX1 may be larger than the size of the openings OP of the first light blocking layer BM1 defining the emission areas EA of the second pixels PX2. Accordingly, the light exit angle or the viewing angle of the second pixels PX2 may be smaller than the light exit angle or the viewing angle of the first pixels PX1. In one embodiment, the light exit angle or viewing angle of the second pixels PX2 may be controlled (e.g., limited) by the second light blocking layer BM2 as well as the size or position of the openings OP of the first light blocking layer BM1.

In one embodiment, the size of the emission areas EA of the first pixels PX1 (or the aperture ratio of the first pixels PX1) may be larger than the size of the emission areas EA of the second pixels PX2 (or the aperture ratio of the second pixels PX2). For example, since the first light blocking layer BM1 surrounds the pixel electrodes AE of the second pixels PX2 at a shorter distance, the size (e.g., area) of the emission areas EA of the second pixels PX2 may be reduced compared to the size (e.g., area) of the emission areas EA of the first pixels PX1. In one embodiment, the areas occupied by each first pixel PX1 and each second pixel PX2 in the display area DA may be substantially the same. Accordingly, the size of the non-emission area of the second pixels PX2 may be larger than the size of the non-emission area of the first pixels PX1.

The color filters CF may be disposed in the respective emission area EA, and may be further disposed around the emission areas EA. For example, the color filters CF may cover the pixel electrodes AE disposed in the respective emission areas EA and the light emitting elements including the pixel electrodes AE, and may extend to the non-emission area around the emission areas EA.

The color filters CF may include first color filters CF1 disposed in the first emission areas EA1, second color filters CF2 disposed in the second emission areas EA2, and third color filters CF3 disposed in the third emission areas EA3. The color filters CF may contain a colorant such as a dye or a pigment that absorbs light of a wavelength band other than a specific wavelength band. The first color filters CF1 may transmit light of the first color emitted from the light emitting elements of the first emission areas EA1, and may absorb and/or block light of another color (e.g., light of the second color and light of the third color). For example, each first color filter CF1 may be a red color filter that selectively transmits only red light emitted from the light emitting element disposed in each first emission area EA1. The second color filters CF2 may transmit light of the second color emitted from the light emitting elements of the second emission areas EA2, and may absorb and/or block light of another color (e.g., light of the first color and light of the third color). For example, each second color filter CF2 may be a green color filter that selectively transmits only green light emitted from the light emitting element disposed in each second emission area EA2. The third color filters CF3 may transmit light of the third color emitted from the light emitting elements of the third emission areas EA3, and may absorb and/or block light of another color (e.g., light of the first color and light of the second color). For example, each third color filter CF3 may be a blue color filter that selectively transmits only blue light emitted from the light emitting element disposed in each third emission area EA3.

The color filters CF may be formed as individual patterns corresponding to the respective emission areas EA, or may be formed entirely in the display area DA. For example, each first color filter CF1 may be formed as an isolated pattern that covers each first emission area EA1 and the periphery of the first emission area EA1, each second color filter CF2 may be formed as an isolated pattern that covers each second emission area EA2 and the periphery of the second emission area EA2, and each third color filter CF3 may be formed as an isolated pattern that covers each third emission area EA3 and the periphery of the third emission area EA3. Alternatively, the first color filter CF1 may include openings formed in areas corresponding to the second emission areas EA2 and the third emission areas EA3, the second color filter CF2 may include openings formed in areas corresponding to the first emission areas EA1 and the third emission areas EA3, and the third color filter CF3 may include openings formed in areas corresponding to the first emission areas EA1 and the second emission areas EA2.

In one embodiment, the first light blocking layer BM1 may be formed as a light blocking pattern other than the color filters CF, or may be formed as a part of the color filters CF. For example, the display device 10 may include the first light blocking layer BM1 formed as a light blocking pattern which is not the color filters CF, or may include the first light blocking layer BM1 formed by overlapping the color filters CF that block light of different colors in the non-emission areas around the emission areas EA.

In one embodiment, the first light blocking layer BM1 and the color filters CF may be disposed on the display layer DU. For example, the first light blocking layer BM1 and the color filters CF may be disposed in the color filter layer CFL of FIG. 3. Since the color filters CF and the first light blocking layer BM1 are disposed on the display layer DU, the intensity of reflected light due to external light may be reduced.

As shown in FIG. 7, the second light blocking layer BM2 may be disposed in some pixels PX among the pixels PX disposed in the display area DA. For example, the second pixels PX2 may include the second light blocking layer BM2. The second light blocking layer BM2 may not be disposed in the first pixels PX1.

The second light blocking layer BM2 may surround the emission areas EA of some pixels PX among the pixels PX. For example, the second light blocking layer BM2 may be disposed in the non-emission area of the second pixels PX2, and may surround the emission areas EA of each of the second pixels PX2. For example, the second light blocking layer BM2 may surround the first emission area EA1, the second emission area EA2, and the third emission area EA3 of each of the second pixels PX2.

In one embodiment, the second light blocking layer BM2 may be disposed on the first light blocking layer BM1 and the color filters CF. For example, the second light blocking layer BM2 may be disposed in the light blocking member layer PML of FIG. 3. In a plan view, the second light blocking layer BM2 may overlap a part of the first light blocking layer BM1. For example, the second light blocking layer BM2, which is disposed on a part of the first light blocking layer BM1, may be disposed in a part of the non-emission area (e.g., a part of the non-emission area of each of the second pixels PX2). Since the second light blocking layer BM2 is disposed on the color filter layer CFL, the light exit angle or viewing angle of the second pixels PX2 may be adjusted or limited.

The light exit angle or viewing angle of the second pixels PX2 may be adjusted or changed by at least one of the size of the openings OP of the first light blocking layer BM1, the separation distance between and the first light blocking layer BM1 and the pixel electrodes AE of the second pixels PX2, the presence/absence of the second light blocking layer BM2, or the separation distance between the second light blocking layer BM2 and the pixel electrodes AE of the second pixels PX2. For example, by disposing the second light blocking layer BM2 in the second pixels PX2 to block at least a part of the side light emitted from the second pixels PX2, the light exit angle or the viewing angle of the second pixels PX2 may be further reduced.

In one embodiment, the second light blocking layer BM2 disposed in one second pixel PX2 may be formed as one pattern. For example, the second light blocking layer BM2 disposed in one second pixel PX2 may include central portions BM2A surrounding the first emission area EA1, the second emission area EA2, and the third emission area EA3, and edge portions BM2B that connect the central portions BM2A. The central portions BM2A of the second light blocking layer BM2 may include respective openings corresponding to the respective emission areas EA, and may have a shape (e.g., a ring shape) surrounding the emission areas EA. The edge portions BM2B of the second light blocking layer BM2 may be disposed between the central portions BM2A, and may be formed integrally with the central portions BM2A. Accordingly, in a pixel process for forming the pixels PX, the second light blocking layer BM2 may be prevented from being deviated from a determined position or being peeled off, and the second light blocking layer BM2 may be more stably formed.

As described above, the display device 10 according to one embodiment may include the first pixels PX1 where the second light blocking layer BM2 is not disposed and the second pixels PX2 where the second light blocking layer BM2 is disposed, and the side visibility may be adjusted depending on the emission mode. Depending on the viewing angle of the display device 10, patterns of the second light blocking layer BM2 (e.g., second light blocking pattern disposed in each second pixel PX2) may partially cover the pixel electrode AE, and may block the emission of light at a specific viewing angle. For example, when the display device 10 is viewed from the side, the second light blocking layer BM2 may block light emitted obliquely from the second pixels PX.

In a state where the side visibility is not limited, which is the first emission mode of the display device 10, both of the first pixels PX1 and the second pixels PX2 may emit light. Since both of the first pixels PX1 and the second pixels PX2 emit light in the first emission mode, the display device 10 may provide a wide viewing angle. For example, regardless of the direction from which the display device 10 is viewed, the light emitted from at least the first pixels PX1 may be visually recognized by the user.

On the other hand, in a state where it is desired to limit the side visibility, which is the second emission mode of the display device 10, the first pixels PX1 may not emit light, and only the second pixels PX2 may emit light. Since only the second pixels PX2 emit light in the second emission mode, the light emitted from the openings OP of the first light blocking layer BM1 may be blocked by the second light blocking layer BM2 at a specific viewing angle. Since the first pixels PX1 do not emit light, the image of the display device 10 in the second emission mode may be visually recognized only by the user looking from the front of the display area DA, and may not be visually recognized by the user looking at an angle greater than a specific viewing angle or from the side. Accordingly, the display device 10 may provide a side viewing angle blocking mode, e.g., a privacy protection mode, to the user.

In the second emission mode of the display device 10, a light leakage phenomenon of light emitted from the second pixels PX2 may occur depending on a degree of light obliquely emitted from the pixel electrodes AE of the second pixels PX2 and blocked by the second light blocking layer BM2. However, in the display device 10 according to one embodiment, the patterns of the second light blocking layer BM2 may have a shape corresponding to the shape of the pixel electrodes AE and may be disposed to surround the emission areas EA where the pixel electrodes AE are disposed. In the second emission mode, the degree in which the pixel electrodes AE of the second pixels PX2 are blocked may be uniform at all viewing angles when viewing the display device 10, and the light leakage phenomenon of light emitted from the light emitting element including the specific pixel electrode AE may be prevented.

Further, in the display device 10 according to one embodiment, the second light blocking layer BM2 is disposed to correspond to the pixel electrodes AE of the second pixels PX2, and thus may be disposed not to affect other adjacent pixels, e.g., the first pixels PX1. Accordingly, in the first emission mode, the second light blocking layer BM2 may not substantially block the light emitted from the emission areas EA of the first pixels PX1.

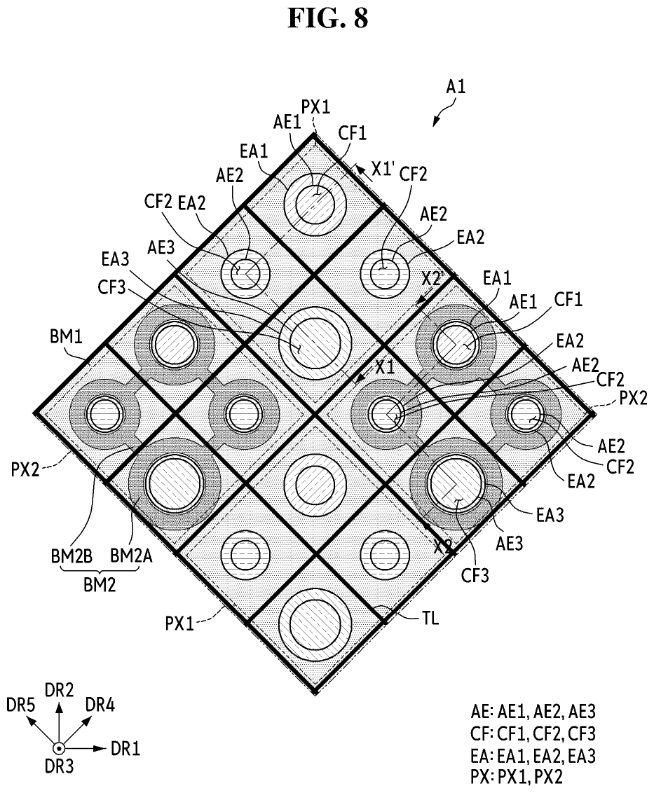

FIG. 8 is a plan view illustrating a display area of a display device according to one embodiment. For example, FIG. 8 shows a touch electrode TL together with the pixel electrodes AE, the first light blocking layer BM1, the color filters CF, and the second light blocking layer BM2 that are disposed in area A1 of FIG. 4.

Referring to FIG. 8 in addition to FIGS. 4 to 7, the display device 10 may further include the touch electrodes TL disposed between the pixel electrodes AE. Although FIG. 8 shows the approximate shape of the touch electrode TL disposed in area A1 of FIG. 4, a plurality of touch electrodes TL may be disposed in the display area DA. For example, when the display device 10 includes a mutual capacitance type touch sensor, the plurality of touch electrodes TL including driving electrodes and sensing electrodes may be disposed in the display area DA.

In one embodiment, the touch electrodes TL may be formed as mesh-shaped patterns including openings exposing the emission areas EA of the pixels PX. For example, each touch electrode TL or each of a plurality of electrode cells constituting the touch electrode TL may be a mesh-shaped pattern formed of thin lines respectively extending in the fourth direction DR4 or the fifth direction DR5 and overlapping the first light blocking layer BM1.

In one embodiment, the resolution of the pixels PX and the resolution of the touch electrodes TL may be different. For example, each touch electrode TL may be disposed in an area where the plurality of pixels PX are disposed. For example, the touch electrode TL shown in FIG. 8 may be one touch electrode TL disposed in area A1 of FIG. 4 or one electrode cell forming the touch electrode TL. The shape, number, resolution, and/or structure of the touch electrodes TL may be variously changed depending on embodiments. In one embodiment, the touch electrodes TL may be connected or extended in a desired shape or direction through respective bridge patterns.

In one embodiment, the touch electrodes TL may be disposed on the display layer DU. For example, the touch electrodes TL may be disposed in the touch sensing layer TSU of FIG. 3. A touch input may be sensed in the display area DA by the touch electrodes TL.

FIG. 9 is a cross-sectional view illustrating a display device according to one embodiment. For example, FIG. 9 shows a portion of the display device 10 corresponding to a cross section of the first pixel PX1 along line X1-X1′ of FIGS. 4 to 8.

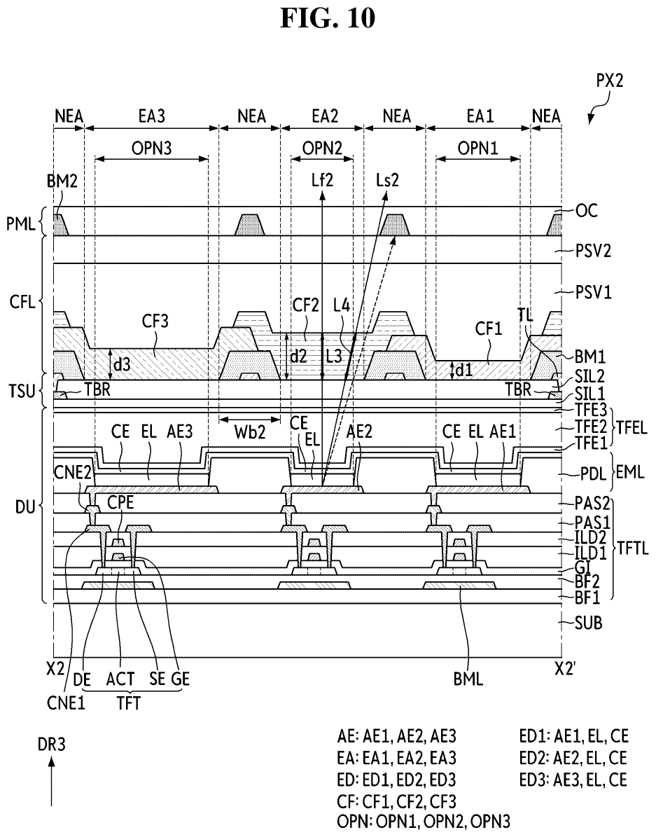

FIG. 10 is a cross-sectional view showing a display device according to one embodiment. For example, FIG. 10 shows a portion of the display device 10 corresponding to a cross section of the second pixel PX2 along line X2-X2′ of FIGS. 4 to 8.

Referring to FIGS. 9 and 10 in addition to FIGS. 1 to 8, the display panel 100 of the display device 10 according to one embodiment may include the display layer DU, the touch sensing layer TSU, the color filter layer CFL, and the light blocking member layer PML.

The display layer DU may include the substrate SUB, the thin film transistor layer TFTL, the light emitting element layer EML, and the encapsulation layer TFEL. The touch sensing layer TSU may include the touch electrodes TL and bridge patterns TBR. The color filter layer CFL may include the first light blocking layer BM1 and the color filters CF. The light blocking member layer PML may include the second light blocking layer BM2 and an overcoat layer OC.

The substrate SUB may be a base substrate or a base member. In one embodiment, the substrate SUB may be a flexible substrate which can be bent, folded or rolled, but is not limited thereto.

The thin film transistor layer TFTL may include a first buffer layer BF1, a lower metal layer BML, a second buffer layer BF2, a thin film transistor TFT, a gate insulating layer G1, a first interlayer insulating layer ILD1, a capacitor electrode CPE, a second interlayer insulating layer ILD2, a first connection electrode CNE1, a first passivation layer PAS1, a second connection electrode CNE2, and a second passivation layer PAS2. However, embodiments are not limited thereto, and the number or type of conductive layers and insulating layers forming the thin film transistor layer TFTL, and/or the structure or type of the thin film transistor TFT may be variously changed depending on embodiments.

The first buffer layer BF1 may be disposed on the substrate SUB. In one embodiment, the first buffer layer BF1 may include an inorganic film capable of preventing penetration of air or moisture.

The lower metal layer BML may be disposed on the first buffer layer BF1. In one embodiment, the lower metal layer BML may be formed as a single layer or multiple layers made of any one of molybdenum (Mo), aluminum (A1), chromium (Cr), gold (Au), titanium (Ti), nickel (Ni), neodymium (Nd) and copper (Cu) or an alloy thereof.

The second buffer layer BF2 may cover the first buffer layer BF1 and the lower metal layer BML. In one embodiment, the second buffer layer BF2 may include an inorganic film capable of preventing penetration of air or moisture.

The thin film transistor TFT may be disposed on the second buffer layer BF2, and may be provided to each of the pixel circuits (e.g., pixel circuits of sub-pixels) included in each pixel PX. FIGS. 9 and 10 show the approximate shape of one thin film transistor TFT (e.g., the thin film transistor TFT electrically connected to the first light emitting element ED1, the second light emitting element ED2, or the third light emitting element ED3) among the thin film transistors TFT that may be provided to the respective pixel circuits (e.g., pixel circuits of sub-pixels) of the first pixel PX1 and the second pixel PX2. Each thin film transistor TFT shown in FIGS. 9 and 10 may be a switching transistor or a driving transistor constituting each pixel circuit. The thin film transistor TFT may include a semiconductor layer ACT, a source electrode SE, a drain electrode DE, and a gate electrode GE.

The semiconductor layer ACT may be disposed on the second buffer layer BF2. The semiconductor layer ACT may overlap the lower metal layer BML and the gate electrode GE in the thickness direction, and may be insulated from the gate electrode GE by the gate insulating layer GI. A part of the semiconductor layer ACT may become conductive to form the source electrode SE (or source region) and the drain electrode DE (or drain region).

The gate electrode GE may be disposed on the gate insulating layer GI. The gate electrode GE may overlap the semiconductor layer ACT with the gate insulating layer GI interposed therebetween.

The gate insulating layer GI may be disposed on the semiconductor layer ACT. For example, the gate insulating layer GI may cover the semiconductor layer ACT and the second buffer layer BF2, and may be disposed between the semiconductor layer ACT and the gate electrode GE. The gate insulating layer GI may include a contact hole through which the first connection electrode CNE1 passes.

The first interlayer insulating layer ILD1 may cover the gate electrode GE and the gate insulating layer GI. The first interlayer insulating layer ILDI may include a contact hole through which the first connection electrode CNE1 passes. The contact hole of the first interlayer insulating layer ILD1 may be connected to the contact hole of the gate insulating layer GI and the contact hole of the second interlayer insulating layer ILD2.

The capacitor electrode CPE may be disposed on the first interlayer insulating layer ILD1. The capacitor electrode CPE may overlap the gate electrode GE in the thickness direction. The capacitor electrode CPE and the gate electrode GE may form a capacitance. For example, a storage capacitor of each pixel circuit may be formed by the capacitor electrode CPE and the gate electrode GE.

The second interlayer insulating layer ILD2 may cover the capacitor electrode CPE and the first interlayer insulating layer ILD1. The second interlayer insulating layer ILD2 may include a contact hole through which the first connection electrode CNE1 passes. The contact hole of the second interlayer insulating layer ILD2 may be connected to the contact hole of the first interlayer insulating layer ILD1 and the contact hole of the gate insulating layer GI.

The first connection electrode CNE1 may be disposed on the second interlayer insulating layer ILD2. The first connection electrode CNE1 may electrically connect the drain electrode DE of the thin film transistor TFT to the second connection electrode CNE2. When the type of the thin film transistor TFT and/or the structure of the pixel circuit is changed, the first connection electrode CNEI may electrically connect the source electrode SE of the thin film transistor TFT to the second connection electrode CNE2. The first connection electrode CNE1 may be in contact with and/or connected to the drain electrode DE of the thin film transistor TFT through a contact hole formed in the second interlayer insulating layer ILD2, the first interlayer insulating layer ILD1, and the gate insulating layer GI.

The first passivation layer PASI may cover the first connection electrode CNE1 and the second interlayer insulating layer ILD2. The first passivation layer PASI may protect the thin film transistor TFT. The first passivation layer PASI may include a contact hole through which the second connection electrode CNE2 passes.

The second connection electrode CNE2 may be disposed on the first passivation layer PAS1. The second connection electrode CNE2 may electrically connect the first connection electrode CNE1 to a pixel electrode AE of the light emitting element ED. The second connection electrode CNE2 may be in contact with and/or connected to the first connection electrode CNE1 through a contact hole formed in the first passivation layer PAS1. Further, the second connection electrode CNE2 may be in contact with and/or connected to the pixel electrode AE of the light emitting element ED through a contact hole formed in the second passivation layer PAS2. In another embodiment, the thin film transistor layer TFTL may not include the second connection electrode CNE2, and the pixel electrode AE of the light emitting element ED may be directly connected to the first connection electrode CNE1 (or one electrode of the thin film transistor TFT).

The second passivation layer PAS2 may cover the second connection electrode CNE2 and the first passivation layer PAS1. The second passivation layer PAS2 may include a contact hole through which the pixel electrode AE of the light emitting element ED passes. In another embodiment, the thin film transistor layer TFTL may not include the second connection electrode CNE2 and the second passivation layer PAS2, and the pixel electrode AE of the light emitting element ED may be disposed on the first passivation layer PAS1.

The light emitting element layer EML may be disposed on the thin film transistor layer TFTL. The light emitting element layer EML may include the light emitting elements ED and the pixel defining film PDL. The light emitting elements ED may be disposed in the respective emission areas EA.

Each light emitting element ED may include the pixel electrode AE (e.g., the first electrode or the anode electrode of the light emitting element ED), the light emitting layer EL, and the common electrode CE (e.g., the second electrode or the cathode electrode of the light emitting element ED). For example, the first light emitting element ED1 disposed in each first emission area EA1 may include the first pixel electrode AE1, and the light emitting layer EL and the common electrode CE that are sequentially disposed on the first pixel electrode AE1. The second light emitting element ED2 disposed in each second emission area EA2 may include the second pixel electrode AE2, and the light emitting layer EL and the common electrode CE that are sequentially disposed on the second pixel electrode AE2. The third light emitting element ED3 disposed in each third emission area EA3 may include the third pixel electrode AE3, and the light emitting layer EL and the common electrode CE that are sequentially disposed on the third pixel electrode AE3.

The pixel electrode AE may be disposed on the second passivation layer PAS2. Different pixel electrodes AE may be arranged in different emission areas EA. For example, the first pixel electrode AE1, the second pixel electrode AE2, and the third pixel electrode AE3 of the first pixel PX1 may be disposed in the first emission area EA1, the second emission area EA2, and the third emission area EA3 of the first pixel PX1, respectively, and the first pixel electrode AE1, the second pixel electrode AE2, and the third pixel electrode AE3 of the second pixel PX2 may be disposed in the first emission area EA1, the second emission area EA2, and the third emission area EA3 of the second pixel PX2, respectively.

In one embodiment, at least a part of each of the pixel electrodes AE may not be covered by the pixel defining film PDL. For example, most of the area of each first pixel electrode AE1 that includes the central portion thereof may not be covered by the pixel defining film PDL, most of the area of each second pixel electrode AE2 that includes the central portion thereof may not be covered by the pixel defining film PDL, and most of the area of each third pixel electrode AE3 that includes the central portion thereof may not be covered by the pixel defining film PDL. The edge portions of the pixel electrodes AE may be covered by the pixel defining film PDL.

The respective light emitting layers EL may be arranged on a part of the pixel electrodes AE not covered by the pixel defining film PDL. Accordingly, each light emitting element ED may be disposed and/or formed in each emission area EA.

The pixel electrode AE may be electrically connected to one electrode of the thin film transistor TFT. For example, the pixel electrode AE may be electrically connected to the drain electrode DE of the thin film transistor TFT through the first connection electrode CNE1 and the second connection electrode CNE2.

The light emitting layer EL may be disposed on the pixel electrode AE. In one embodiment, the light emitting layer EL may be an organic light emitting layer made of an organic material, but is not limited thereto.

In one embodiment, the light emitting layers EL of the first light emitting element

ED1, the second light emitting element ED2, and the third light emitting element ED3 may emit light of different colors. For example, the light emitting layer EL of the first light emitting element ED1 may emit light of the first color, e.g., red light, the light emitting layer EL of the second light emitting element ED2 may emit light of the second color, e.g., green light, and the light emitting layer EL of the third light emitting element ED3 may emit light of the third color, e.g., blue light.

However, the embodiments are not limited thereto. For example, in another embodiment, the light emitting layer EL of the light emitting elements ED may be formed as one common layer entirely disposed on the different pixel electrodes AE and the pixel defining film PDL, and the light emitting layer EL disposed on different pixel electrodes AE may emit light of the same color. In this case, the display device 10 may further include a color adjustment layer (e.g., color conversion layer including wavelength conversion patterns and/or color adjustment layer including the color filters CF) disposed on the light emitting elements ED.

The common electrode CE may be disposed on the light emitting layer EL of each of the light emitting elements ED. In one embodiment, the common electrode CE may be formed as one common layer disposed entirely in the display area DA, and the light emitting elements ED of the pixels PX may share one common electrode CE. The common electrode CE may receive a common voltage (e.g., second pixel voltage or cathode voltage).

The pixel defining film PDL may include the openings OPN corresponding to the emission areas EA and may be disposed on a part of the pixel electrodes AE and the second passivation layer PAS2. For example, the pixel defining film PDL may be disposed at least in the non-emission area NEA, and may include the first opening OPN1 disposed in each first emission area EA1, the second opening OPN2 disposed in each second emission area EA2, and the third opening OPN3 disposed in each third emission area EA3.

In one embodiment, the openings OPN of the pixel defining film PDL may have a size smaller than that of each of the emission areas EA, and may be disposed in the emission areas EA. However, the embodiments are not limited thereto. For example, the openings OPN of the pixel defining film PDL may have substantially the same size as that of each of the emission areas EA. The pixel defining film PDL may overlap the first light blocking layer BM1 and the second light blocking layer BM2 in a plan view.

In one embodiment, the openings OPN of the pixel defining film PDL may have different sizes. For example, the openings OPN of the pixel defining film PDL may have sizes corresponding to those of the respective emission areas EA. For example, the size of each first opening OPN1 (or a first aperture ratio corresponding to the first emission area EA1) may be larger than the size) of each second opening OPN2 (or a second aperture ratio corresponding to the second emission area EA2, and may be smaller than the size of each third opening OPN3 (or a third aperture ratio corresponding to the third emission area EA3).

In one embodiment, the pixel defining film PDL may be opened with substantially the same area in a first pixel area where each first pixel PX1 is disposed and in a second pixel area where each second pixel PX2 is disposed. For example, the size of the first opening OPN1 disposed in the first emission area EA1 of the first pixel PX1 and the size of the first opening OPN1 disposed in the first emission area EA1 of the second pixel PX2 may be substantially the same or similar. Similarly, the size of the second opening OPN2 disposed in the second emission area EA2 of the first pixel PX1 and the size of the second opening OPN2 disposed in the second emission area EA2 of the second pixel PX2 may be substantially the same or similar, and the size of the third opening OPN3 disposed in the third emission area EA3 of the first pixel PX1 and the size of the third opening OPN3 disposed in the third emission area EA3 of the second pixel PX2 may be substantially the same or similar. However, when the first light blocking layer BM1 is opened narrower in the second pixel PX2 than the first pixel PX1, the actual size of the emission areas EA (e.g., the light emitting area) of the second pixel PX2 may be smaller than the actual size of the emission areas EA of the first pixel PX1.

In one embodiment, the pixel defining film PDL may include a light absorbing material to prevent light reflection. For example, the pixel defining film PDL may include a polyimide (PI)-based binder and a pigment in which red, green, and blue colors are mixed. Alternatively, the pixel defining film PDL may include a cardo-based binder resin and a mixture of a lactam black pigment and a blue pigment. Alternatively, the pixel defining film PDL may include carbon black.

The encapsulation layer TFEL may be disposed on the common electrode CE to cover the light emitting elements ED. In one embodiment, the encapsulation layer TFEL may include at least one inorganic film to prevent oxygen or moisture from permeating into the light emitting element layer EML, and may include at least one organic film to protect the light emitting element layer EML from foreign substances such as dust.

In one embodiment, the encapsulation layer TFEL may include a first encapsulation layer TFE1, a second encapsulation layer TFE2, and a third encapsulation layer TFE3 sequentially disposed on the light emitting elements ED. The first encapsulation layer TFE1 and the third encapsulation layer TFE3 may be inorganic encapsulation layers, and the second encapsulation layer TFE2 disposed between the first encapsulation layer TFE1 and the third encapsulation layer TFE3 may be an organic encapsulation layer.

Each of the first encapsulation layer TFE1 and the third encapsulation layer TFE3 may include an inorganic insulating material. For example, each of the first encapsulation layer TFE1 and the third encapsulation layer TFE3 may include aluminum oxide, titanium oxide, tantalum oxide, hafnium oxide, zinc oxide, silicon oxide, silicon nitride, silicon oxynitride and/or another inorganic insulating material.

The second encapsulation layer TFE2 may include an organic insulating material. For example, the second encapsulation layer TFE2 may include a polymer-based organic insulating material such as acrylic resin, epoxy resin, polyimide, or polyethylene, or may include another organic insulating material. The second encapsulation layer TFE2 may be formed by curing a monomer or applying a polymer.

The touch sensing layer TSU may be disposed on the encapsulation layer TFE1. For example, the touch sensing layer TSU may be disposed between the display layer DU and the color filter layer CFL. However, embodiments are not limited thereto, and the location of the touch sensing layer TSU may vary depending on embodiments. In another embodiment, the touch sensing layer TSU and the display layer DU may be integrated, or the display device 10 may not include a separate touch sensing layer TSU. In this case, the color filter layer CFL may be disposed directly on the display layer DU.

The touch sensing layer TSU may include a first insulating layer SIL1, a second insulating layer SIL2, and the touch electrode TL. In one embodiment, the touch sensing layer TSU may further include at least one insulating layer covering the second insulating layer SIL2 and the touch electrode TL.

The touch sensing layer TSU may include conductive patterns including the touch electrode TL. The conductive patterns may be sensing patterns used for sensing a touch input. For example, the conductive patterns of the touch sensing layer TSU may be utilized to sense a change in electrical characteristics (e.g., a change in capacitance) according to a touch input, and to detect the touch input.

In one embodiment, the conductive patterns of the touch sensing layer TSU may further include the bridge patterns TBR for connecting the touch electrodes TL (or electrode cells forming the touch electrodes TL) disposed in the display area DA in a desired shape and/or structure. Each bridge pattern TBR may overlap a part of at least one touch electrode TL (e.g., two electrode cells included in the touch electrode TL and adjacent to each other), and may be electrically connected to the touch electrode TL.

In one embodiment, the conductive patterns of the touch sensing layer TSU may be disposed in the non-emission area NEA around the emission areas EA, and may be overlapped with the first light blocking layer BM1. Accordingly, the conductive patterns of the touch sensing layer TSU may be prevented from being visually recognized by the user.

In one embodiment, the touch sensing layer TSU may include a plurality of conductive layers. For example, the touch sensing layer TSU may include a first conductive layer (e.g., a lower conductive layer) including the bridge patterns TBR and a second conductive layer (e.g., an upper conductive layer) including the touch electrodes TL. At least one insulating layer may be disposed between the first conductive layer and the second conductive layer. For example, the second insulating layer SIL2 may be disposed between the first conductive layer and the second conductive layer. In one embodiment, the first conductive layer may be disposed under the second insulating layer SIL2, and the second conductive layer may be disposed over the second insulating layer SIL2, but the present disclosure is not limited thereto. For example, the arrangement order or position of the first conductive layer and the second conductive layer may be changed.

The first insulating layer SIL1 may be disposed on the encapsulation layer TFEL. The first insulating layer SIL1 may have an insulating function and an optical function. In one embodiment, the first insulating layer SIL1 may include at least one inorganic film. The first insulating layer SIL1 may be omitted.

The bridge pattern TBR may be disposed on the first insulating layer SIL1. The position of the bridge pattern TBR may vary according to embodiments.

The second insulating layer SIL2 may be disposed on the bridge pattern TBR. For example, the second insulating layer SIL2 may cover the bridge pattern TBR and the first insulating layer SIL1, and may be disposed between the touch electrode TL and the bridge pattern TBR. The second insulating layer SIL2 may include a contact hole through which the touch electrode TL (or the bridge pattern TBR) passes at a portion where the touch electrode TL and the bridge pattern TBR are connected.

The second insulating layer SIL2 may have an insulating function and an optical function. In one embodiment, the second insulating layer SIL2 may be an inorganic film containing at least one of a silicon nitride layer, a silicon oxynitride layer, a silicon oxide layer, a titanium oxide layer, or an aluminum oxide layer.

The touch electrode TL (or a part of the touch electrodes TL in the display area DA) may be disposed on the second insulating layer SIL2. The touch electrode TL may include a conductive material and may be formed as a single layer or multiple layers. For example, the touch electrode TL may be formed as a single layer containing molybdenum (Mo), titanium (Ti), copper (Cu), aluminum (A1), or indium tin oxide (ITO), or may be formed to have a stacked structure (Ti/Al/Ti) of aluminum and titanium, a stacked structure (ITO/AI/ITO) of aluminum and ITO, an Ag—Pd—Cu (APC) alloy, or a stacked structure (ITO/APC/ITO) of APC alloy and ITO.

In one embodiment, the touch electrode TL may not overlap the pixel electrodes AE. For example, the touch electrode TL may be disposed in the non-emission area NEA, and may be overlapped with the pixel defining film PDL and the first light blocking layer BM1.

In one embodiment, the first light blocking layer BM1 may have a width enough to completely cover the touch electrode TL. In one embodiment, the touch electrode TL may be disposed such that the center thereof is almost parallel to the center of the first light blocking layer BM1, and the gap from both sides of the touch electrode TL to the edge of the first light blocking layer BM1 may be uniform.

The color filter layer CFL may be disposed on the light emitting element layer EML. For example, the color filter layer CFL may be disposed on the touch sensing layer TSU, and may cover the light emitting element layer EML, the encapsulation layer TFE1, and the touch sensing layer TSU.

The color filter layer CFL may include the first light blocking layer BM1, the color filters CF, and at least one passivation layer. For example, the color filter layer CFL may include the first light blocking layer BM1, the color filters CF, the first passivation layer PSV1, and the second passivation layer PSV2.

Although FIGS. 9 and 10 illustrate an embodiment in which the first light blocking layer BM1 and the color filters CF are formed separately from each other, embodiments are not limited thereto. For example, a display device 10 according to another embodiment may not include the first light blocking layer BM1 of FIGS. 9 and 10 formed separately, and light may be blocked by arranging the first color filter CF1, the second color filter CF2, and the third color filter CF3 to overlap each other in the non-emission area NEA. In this case, the first color filter CF1 may be disposed in area corresponding to the first emission areas EA1 and the non-emission area NEA, and include openings disposed corresponding to the second emission areas EA2 and the third emission areas EA3. The second color filter CF2 may be disposed in area corresponding to the second emission areas EA2 and the non-emission area NEA, and include openings disposed corresponding to the first emission areas EA1 and the third emission areas EA3. The third color filter CF3 may be disposed in area corresponding to the third emission areas EA3 and the non-emission area NEA, and include openings disposed corresponding to the first emission areas EA1 and the second emission areas EA2.

The first light blocking layer BM1 may be disposed on the touch sensing layer TSU. The first light blocking layer BM1 may be disposed in the non-emission area NEA. The first light blocking layer BM1 may cover the touch electrode TL. The first light blocking layer BM1 may include a light blocking material (e.g., a light absorbing material) such as a black matrix material.

The first light blocking layer BM1 may not cover the openings OP exposing the pixel electrodes AE. For example, as illustrated in FIG. 6, the first light blocking layer BM1 may include the first opening OP1 disposed in each first emission area EA1 not to cover the first pixel electrode AE1, the second opening OP2 disposed in each second emission area EA2 not to cover the second pixel electrode AE2, and the third opening OP3 disposed in each third emission area EA3 not to cover the third pixel electrode AE3.

In one embodiment, the first light blocking layer BM1 may be opened with different sizes in the first pixel PX1 and the second pixel PX2. For example, the area (or width) of the first opening OP1, the second opening OP2, and the third opening OP3 that are disposed in the first emission area EA1, the second emission area EA2, and the third emission area EA3 of the first pixel PX1 may be greater than the area (or width) of the first opening OP1, the second opening OP2, and the third opening OP3 that are disposed in the first emission area EA1, the second emission area EA2, and the third emission area EA3 of the second pixel PX2, respectively.

Accordingly, the first light blocking layer BM1 may have different widths in the non-emission area NEA of the first pixel PX1 and the non-emission area NEA of the second pixel PX2. For example, as illustrated in FIGS. 9 and 10, the first light blocking layer BM1 may have a first width Wb1 and a second width Wb2 in the non-emission area NEA of the first pixel PX1 and the non-emission area NEA of the second pixel PX2, respectively, and the first width Wb1 may be less than the second width Wb2. Accordingly, the side light blocking ratio of the second pixel PX2 may be higher than the side light blocking ratio of the first pixel PX1, and the light exit angle or the viewing angle (e.g., the side viewing angle) of the second pixel PX2 may be narrower than the light exit angle or the viewing angle of the first pixel PX1.

The color filters CF may be disposed on the touch sensing layer TSU and the first light blocking layer BM1. The color filters CF may be disposed in the respective emission areas EA and overlap the respective light emitting elements ED. In one embodiment, the color filters CF may also be disposed around the respective emission areas EA, and at least two color filters CF may overlap each other between adjacent emission areas EA.

The first color filter CF1 may be disposed in the first emission area EA1 and overlap the first light emitting element ED1. In one embodiment, the edge portion of the first color filter CF1 may be disposed around the first emission area EA1 and overlap a part of the first light blocking layer BM1. For example, in a plan view, the edge portion of the first color filter CF1 may surround the first emission area EA1, and may be disposed on a part of the first light blocking layer BM1.

The second color filter CF2 may be disposed in the second emission area EA2 and overlap the second light emitting element ED2. In one embodiment, the edge portion of the second color filter CF2 may be disposed around the second emission area EA2 and overlap a part of the first light blocking layer BM1. For example, in a plan view, the edge portion of the second color filter CF2 may surround the second emission area EA2, and may be disposed on a part of the first light blocking layer BM1.

The third color filter CF3 may be disposed in the third emission area EA3 and overlap the third light emitting element ED3. In one embodiment, the edge portion of the third color filter CF3 may be disposed around the third emission area EA3 and overlap a part of the first light blocking layer BM1. For example, in a plan view, the edge portion of the third color filter CF3 may surround the third emission area EA3, and may be disposed on a part of the first light blocking layer BM1.

In one embodiment, the color filters CF may have thicknesses that are adjusted or optimized according to the light efficiency of the pixels PX. For example, the color filters CF may have thicknesses that are different from each other or optimized according to the light emission efficiency of light generated from the respective light emitting elements ED, for example, the color filter transmittance of light generated from the respective light emitting elements ED.

In one embodiment, the first color filter CF1 may have a first thickness d1 that is adjusted according to the light emission efficiency of the first color light emitted from the first light emitting element ED1, the second color filter CF2 may have a second thickness d2 that is adjusted according to the light emission efficiency of the second color light emitted from the second light emitting element ED2, and the third color filter CF3 may have a third thickness d3 that is adjusted according to the light emission efficiency of the third color light emitted from the third light emitting element ED3. The thickness of the first color filters CF1 arranged in the first emission areas EA1 may be uniform overall. For example, the first color filters CF1 arranged in the first emission areas EA1 of the first pixels PX1 and the first emission areas EA1 of the second pixels PX2 may have substantially the same first thickness d1 in the respective emission areas EA. The thickness of the second color filters CF2 arranged in the second emission areas EA2 may be uniform overall. For example, the second color filters CF2 arranged in the second emission areas EA2 of the first pixels PX1 and the second emission areas EA2 of the second pixels PX2 may have substantially the same second thickness d2 in the respective emission areas EA. The thickness of the third color filters CF3 arranged in the third emission areas EA3 may be uniform overall. For example, the third color filters CF3 arranged in the third emission areas EA3 of the first pixels PX1 and the third emission areas EA3 of the second pixels PX2 may have substantially the same third thickness d3 in the respective emission areas EA. In describing embodiments, the thicknesses of the color filters CF may be compared with respect to the central portions of the color filters CF arranged in the emission areas EA. For example, the central portions of the first color filters CF1, the second color filters CF2, and the third color filters CF3 may have substantially the first thickness d1, the second thickness d2, and the third thickness d3, respectively.

In one embodiment, the first thickness d1 may be less than the second thickness d2 and the third thickness d3, and the second thickness d2 may be greater than the first thickness d1 and the third thickness d3. For example, the first color filter CF1 may have the thinnest thickness, and the second color filter CF2 may have the thickest thickness. The third color filter CF3 may have an intermediate thickness. However, embodiments are not limited thereto, and the thicknesses of the color filters CF may vary depending on the light emission efficiency of the respective light emitting elements ED, the optimal ratio of the first color light, the second color light, and the third color light that are emitted from the respective emission areas EA, or other various factors.

The first passivation layer PSV1 and the second passivation layer PSV2 may be sequentially disposed on the first light blocking layer BM1 and the color filters CFL. The first passivation layer PSV1 and the second passivation layer PSV2 may be entirely disposed in the display area DA, thereby flattening the stepped portion caused by the color filters CF and the first light blocking layer BM1.

The first passivation layer PSV1 and the second passivation layer PSV2 may be light transmissive layers. For example, the first passivation layer PSV1 and the second passivation layer PSV2 may include a colorless light transmissive organic material such as an acrylic resin.

The light blocking member layer PML may be disposed on the color filter layer CFL. The light blocking member layer PML may include the second light blocking layer BM2 and an overcoat layer OC.

The second light blocking layer BM2 may be disposed on the color filter layer CFL. The second light blocking layer BM2 may include a light blocking material such as a black matrix material. The material of the first light blocking layer BM1 and the material of the second light blocking layer BM2 may be the same or different.

The second light blocking layer BM2 may not be disposed in the first pixels PX1, and may be disposed only in the second pixels PX2. The second light blocking layer BM2 may be disposed in the non-emission area NEA of the second pixels PX2, and may surround the emission areas EA of the second pixels PX2 in a plan view. In one embodiment, the second light blocking layer BM2 may have a width less than that of the first light blocking layer BM1, but is not limited thereto. The size, shape, and/or position of the second light blocking layer BM2 may be adjusted or changed depending on the target viewing angle range of the second pixels PX2.

The overcoat layer OC may be disposed on the second light blocking layer BM2. The overcoat layer OC may cover the color filter layer CFL and the second light blocking layer BM2.

In the display device 10 according to embodiments, color filter transmission lengths according to paths where the light emitted in a front direction, e.g., the third direction DR3, (hereinafter, referred to as front light) and the light emitted in a side direction from the light emitting element ED (hereinafter, referred to as side light) disposed in each emission area EA transmit through each color filter CF may be different. For example, color filter transmission lengths L1 and L3 in which first front light Lf1 emitted in the third direction DR3 from the second light emitting element ED2 of the first pixel PX1 and second front light Lf2 emitted in the third direction DR3 from the second light emitting element ED2 of the second pixel PX2 transmit through the second color filter CF2 may correspond to the second thickness d2 of the second color filter CF2. On the other hand, color filter transmission length L2 and L4 in which first side light Ls1 emitted from the second light emitting element ED2 of the first pixel PX1 and second side light Ls2 emitted from the second light emitting element ED2 of the second pixel PX2 transmit through the second color filter CF2 may be greater than the second thickness d2 of the second color filter CF2. The color filter transmission length of the side light emitted from the respective light emitting elements ED may vary depending on the thickness of each color filter CF and the traveling angle of the side light.

A part of the side light emitted from each emission area EA of the second pixel PX2 and transmitted through the color filter layer CFL may travel toward the second light blocking layer BM2 as indicated by the dotted arrow in FIG. 10 and then blocked by the second light blocking layer BM2. Accordingly, the side light of the second pixel PX2 may be reduced. For example, the side light emission ratio of the second pixel PX2 may be lower than the side light emission ratio of the first pixel PX1.

Further, even in each pixel PX, the light emission ratio of the side light emitted from the respective light emitting elements ED may be different depending on the size or ratio of the emission areas EA. For example, the size of the second emission area EA2 may be smaller than the size of each of the first emission area EA1 and the third emission area EA3, so that the light emission ratio of the side light of the second color may be lower than the light emission ratio of the side light of the first color and the light emission ratio of the side light of the third color. Accordingly, color shift may occur when an image displayed in the display area DA is viewed from the side. For example, the side light emission ratio of the second color light may be lower than the side light emission ratio of the first color light and the side light emission ratio of the third color light, so that the viewing angle color shift may occur, and the side color of the image may be changed.

Further, since the side light emission ratios of the first pixels PX1 and the second pixels PX2 are different, the side colors of the first pixels PX1 and the second pixels PX2 may also be different. For example, the viewing angle color shift of the light emitted from the first pixels PX1 may be different from the viewing angle color shift of the light emitted from the second pixels PX2. For example, the reduction rate of the side light emitted from the second light emitting elements ED2 of the second pixels PX2 may be greater than the reduction rate of the side light emitted from the second light emitting elements ED2 of the first pixels PX1. Accordingly, in the first emission mode in which both the first pixels PX1 and the second pixels PX2 are driven, stains of a pixel unit may be visually recognized when the image displayed in the display area DA is viewed from the side.

In addition, even in the first emission mode in which a wider viewing angle is provided, the side luminance of the image displayed in the display area DA may be reduced overall due to the second pixels PX2 having a low side luminance. The side light blocking rate or the viewing angle of the second pixels PX2 may be appropriately adjusted or changed by comprehensively considering the side luminance in the first emission mode and the side light blocking rate in the second emission mode.

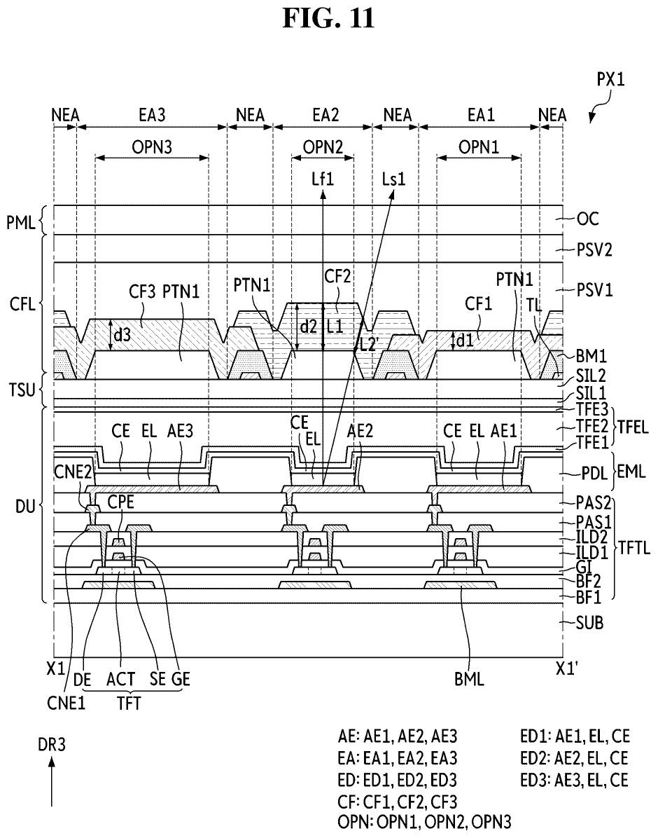

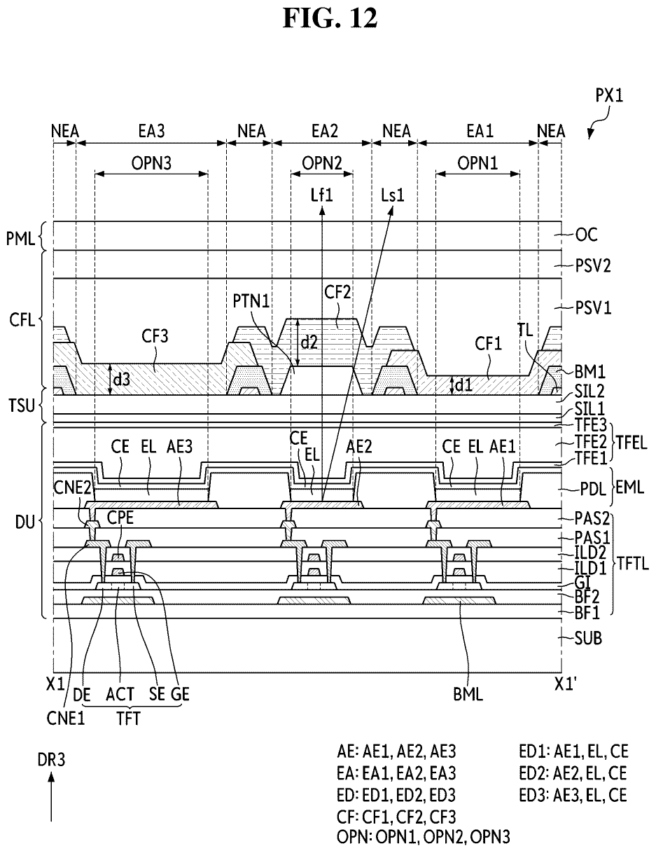

FIG. 11 is a cross-sectional view showing a display device according to one embodiment. FIG. 12 is a cross-sectional view illustrating a display device according to one embodiment. For example, FIGS. 11 and 12, which show different embodiments of a part of the display device 10 that corresponds to the cross section of the first pixel PX1 along line X1-X1′ of FIGS. 4 to 8, show embodiments different from the embodiment of FIG. 9 in relation to the color filter layer CFL.

In describing the following embodiments, components substantially identical or similar to those of at least one embodiment described above are designated with the same reference numerals, and redundant descriptions will be omitted. Further, each embodiment may be applied alone or in combination with at least one other embodiment, and all possible combinations of embodiments may fall within the scope of the present disclosure.

Referring to FIGS. 11 and 12, the display device 10 according to one embodiment may further include a first pattern PTN1 (also referred to as “first light control layer” or “first profile control layer”) disposed in the color filter layer CFL. The first pattern PTN1 may be disposed in a first pixel area where each first pixel PX1 is disposed, and may be disposed in at least one emission area EA among the emission areas EA of the first pixel PX1. In each emission area EA where the first pattern PTN1 is disposed, the first pattern PTN1 may be disposed under the color filter CF. In one embodiment, the first pattern PTN1 may be formed as an isolated pattern disposed in each emission area EA, and may be spaced apart from the first light blocking layer BM1. The first pattern PTN1 may be surrounded by the first light blocking layer BM1 in a plan view.

The first pattern PTN1 may be a light transmitting pattern. For example, the first pattern PTN1 may be substantially transparent, and thus may have a light transmitting property. Accordingly, light emitted from each light emitting element ED may transmit through the first pattern PTN1. The first pattern PTN1 may be formed of an organic material or an inorganic material, and the material of the first pattern PTN1 is not particularly limited.

In one embodiment, the first pattern PTN1 may be disposed on the light emitting element ED disposed in each emission area EA, and may cover the light emitting element ED. For example, in the emission area EA where the first pattern PTN1 is disposed, the first pattern PTN1 may partially or entirely cover the opening OPN of the pixel defining film PDL. Accordingly, in the emission area EA where the first pattern PTN1 is disposed, front light (e.g., the first front light Lf1) emitted from the light emitting element ED may transmit through the first pattern PTN1 and a part of the color filter CF disposed on the first pattern PTN1. Further, in the emission area EA where the first pattern PTN1 is disposed, at least a part of the side light (e.g., the first side light Ls1) emitted from the light emitting element ED may transmit through the first pattern PTN1 and a part of the color filter CF disposed on the first pattern PTN1.

The color filter CF disposed on the first pattern PTN1 may have a surface contour similar to that of the first pattern PTN1. For example, the color filter CF disposed on the first pattern PTN1 may protrude in the height direction (e.g., the third direction DR3) due to the first pattern PTN1, and thus may have a substantially convex cross-sectional shape. For example, the color filter CF disposed on the first pattern PTN1 may include a central portion that is disposed on the first pattern PTN1 in each emission area EA and protrudes more upward than the periphery to have a convex shape, and an edge portion that surrounds the central portion and has a height lower than that of the central portion. The edge portion may extend to the non-emission area NEA, and may overlap the first light blocking layer BM1 in the non-emission area NEA.

In one embodiment, the central portion of the color filter CF may have a thickness that is set according to the light emission efficiency of the light emitting element ED or the like regardless of whether or not the first pattern PTN1 is disposed. For example, the central portions of the first color filter CF1, the second color filter CF2, and the third color filter CF3 of the first pixel PX1 may have the first thickness d1, the second thickness d2, and the third thickness d3, respectively.

In one embodiment, the first pattern PTN1 may be disposed in all the emission areas EA of the first pixel PX1. For example, as illustrated in FIG. 11, the first pattern PTN1 may be disposed in each of the first emission area EA1, the second emission area EA2, and the third emission area EA3 of the first pixel PX1.

The first color filter CF1, the second color filter CF2, and the third color filter CF3 of the first pixel PX1 arranged on each first pattern PTN1 may protrude in the height direction due to each first pattern PTN1. Accordingly, the first color filter CF1, the second color filter CF2, and the third color filter CF3 of the first pixel PX1 may have a substantially convex shape in the central portion located in each emission area EA. For example, each of the first color filter CF1, the second color filter CF2, and the third color filter CF3 of the first pixel PX1 may have a central portion disposed on each first pattern PTN1 and protruding in the height direction, and an edge portion surrounding the central portion and having a height lower than that of than the central portion.

Since the central portion of each of the first color filter CF1, the second color filter CF2, and the third color filter CF3 of the first pixel PX1 protrudes in the height direction due to the first pattern PTN1, the side light emitted from the first emission area EA1, the second emission area EA2, and the third emission area EA3 of the first pixel PX1 may increase. For example, compared to the first pixel PX1 of FIG. 9 that does not include the first pattern PTN1, in the first pixel PX1 of FIG. 11, the color filter transmission length (e.g., a color filter transmission length L2′ of the first side light Ls1) of at least a part of the side light (e.g., the first side light Ls1) may be reduced or minimized. Accordingly, the amount of side light emitted from the first pixel PX1 increases, thereby improving the side luminance of the first pixel PX1.

In another embodiment, the first pattern PTN1 may be disposed only in some emission areas EA among the emission areas EA of the first pixel PX1. For example, the first pattern PTN1 may be disposed only in the emission area EA that emits light of a specific color (e.g., light of the first color, light of the second color, or light of the third color) among the emission areas EA of the first pixel PX1, and may not be disposed in the other emission areas EA. For example, as illustrated in FIG. 12, the first pattern PTN1 may be disposed only in the second emission area EA2 of the first pixel PX1, and may not be disposed in the first emission area EA1 and the third emission area EA3 of the first pixel PX1. Alternatively, the first pattern PTN1 may be disposed in the plurality of emission areas EA that emit light of different colors, and may not be disposed in the other emission areas EA.

The color filter CF disposed in the emission area EA where the first pattern PTN1 is not disposed among the emission areas EA of the first pixel PX1 may have an overall concave shape. For example, the color filter CF disposed in the emission area EA where the first pattern PTN1 is not disposed may include a central portion disposed in each emission area EA, and an edge portion surrounding the central portion and having a height higher than that of the central portion.

In one embodiment, at least one emission area EA that has a greater influence on the side luminance or the side color of the first pixel PX1 may be selected, the first pattern PTN1 may be disposed only in the at least one emission area EA, and the first pattern PTN1 may not be disposed in the other emission areas EA of the first pixel PX1. For example, depending on the colors of light emitted from the respective emission areas EA or the sizes of the emission areas EA, the first pattern PTN1 may be selectively disposed only in some emission areas EA including at least one emission area EA that has a greater influence on the side luminance or the side color. In terms of an emission color, when the first color light, the second color light, and the third color light emitted from the first emission area EA1, the second emission area EA2, and the third emission area EA3 of the first pixel PX1 are red light, green light, and blue light, respectively, the first pattern PTN1 may be disposed at least in the second emission area EA2 of the first pixel PX1. In terms of the light emitting area, when the size of the second emission area EA2 is smallest among the first emission area EA1, the second emission area EA2, and the third emission area EA3 of the first pixel PX1, the first pattern PTN1 may be disposed at least in the second emission area EA2 of the first pixel PX1. Accordingly, the color filter transmission length L2′ of the first side light Ls1 of the second color emitted from the first pixel PX1 may be reduced, so that the luminance of the first side light Ls1 of the second color may increase.

At least one other color filter CF disposed in the emission area EA where the first pattern PTN1 is not disposed may include a central portion disposed in each emission area EA, and an edge portion surrounding the central portion and having a height higher than that of the central portion. For example, the first pattern PTN1 may not be disposed in the first emission area EA1 and the third emission area EA3 of the first pixel PX1. Accordingly, the first color filter CF1 and the third color filter CF3 of the first pixel PX1 may have shapes that are substantially the same as or similar to those in the embodiment of FIG. 9, and the luminances of the first color side light and the third color side light of the first pixel PX1 may be substantially the same as or similar to those in the embodiment of FIG. 9.

By increasing the side light of a specific color emitted from the first pixel PX1, for example, the first side light Ls1 of the second color, the side color of the first pixel PX1 may be adjusted (or, corrected) or improved. For example, when the side light reduction rate of the first pixel PX1 where the first pattern PTN1 is not disposed is highest in the first side light Ls1 of the second color as in FIG. 9, the side color of the first pixel PX1 is more biased toward the first color or the second color and may become reddish or blueish. On the other hand, when the first pattern PTN1 is disposed in the second emission area EA2 of the first pixel PX1 as in FIG. 11, the first side light Ls1 of the green color emitted from the second emission area EA2 of the first pixel PX1 increases, so that the side luminance and the side color of the first pixel PX1 may be adjusted or improved.

However, embodiments are not limited to the case of adjusting the side color of the first pixel PX1 by increasing the first side light Ls1 of the second color emitted from the first pixel PX1. For example, in another embodiment, the side color of the first pixel PX1 may be adjusted or improved in a desired manner by disposing the first pattern PTN1 in at least one of the first emission area EA1 or the third emission area EA3 to increase at least one of the side light of the first color or the side light of the third color.

According to the embodiments of FIGS. 11 and 12, by improving the side luminance of the first pixels PX1 by forming the first pattern PTN1 in each of the emission areas EA, the luminance of the display device 10 in the first emission mode may be improved. In some embodiments, by selectively disposing the first pattern PTN1 only in at least one emission area EA among the emission areas EA of the first pixels PX1, the side luminance and/or side color of the first pixels PX1 may be appropriately adjusted or improved.

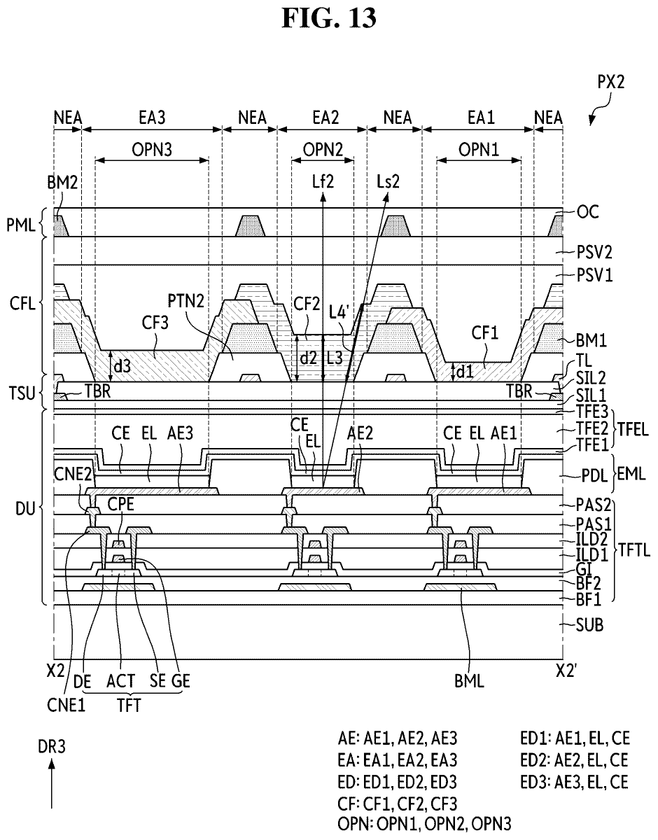

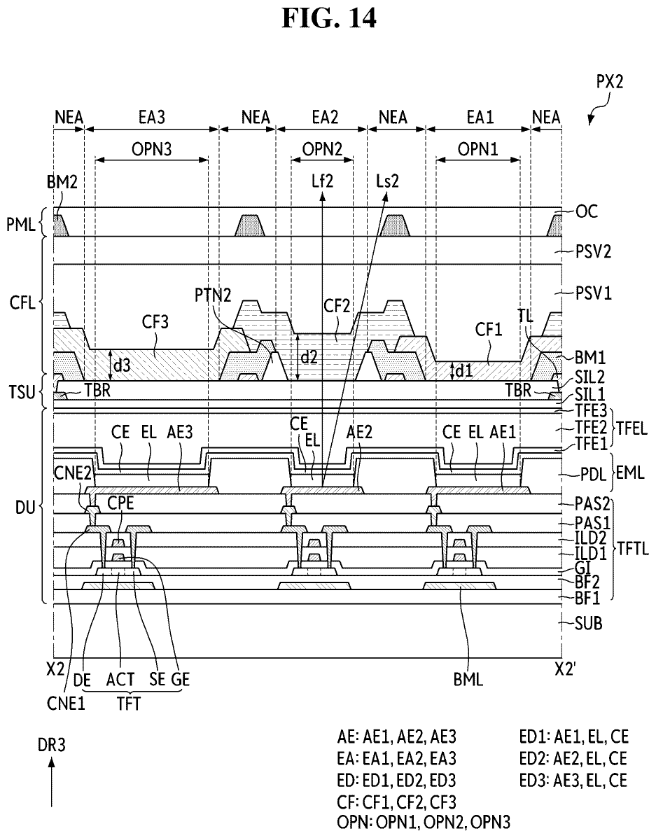

FIG. 13 is a cross-sectional view showing a display device according to one embodiment. FIG. 14 is a cross-sectional view illustrating a display device according to one embodiment. For example, FIGS. 13 and 14, which show different embodiments of a part of the display device 10 corresponding to the cross section of the second pixel PX2 along line X2-X2″ of FIGS. 4 to 8, show embodiments different from the embodiment of FIG. 10 in relation to the color filter layer CFL.

Referring to FIGS. 13 and 14, the display device 10 according to one embodiment may further include a second pattern PTN2 (also referred to as “second light control layer” or “second profile control layer”) disposed in the color filter layer CFL. The second pattern PTN2 may be disposed in the second pixel area where each second pixel PX2 is disposed, and may be disposed in the non-emission area NEA of the second pixel PX2. For example, the second pattern PTN2 may be disposed under at least one of the color filters CF disposed in the emission areas EA of the second pixel PX2 in the non-emission area NEA around the emission areas EA of the second pixel PX2.

The second pattern PTN2 may overlap the first light blocking layer BM1 in the non-emission area NEA of the second pixel PX2. In one embodiment, the second pattern PTN2 may be disposed under the first light blocking layer BM1, and may have a width greater than that of the first light blocking layer BM1. However, the embodiments are not limited thereto. For example, at least one of the mutual positions or the sizes of the first light blocking layer BM1 and the second pattern PTN2 may be changed.

The second pattern PTN2 may or may not have a light transmitting property. For example, the second pattern PTN2 may be a light transmitting pattern formed simultaneously with the first pattern PTN1 using the same material as the first pattern PTN1, and may be substantially transparent. Alternatively, the second pattern PTN2 may be formed as an opaque light blocking pattern unlike the first pattern PTN1. When the second pattern PTN2 has a light blocking property, the side light of the second pixel PX2 may be more effectively reduced or blocked. The second pattern PTN2 may be formed of an organic material or an inorganic material, and the material of the second pattern PTN2 is not particularly limited.

The color filters CF of the second pixel PX2 may have a lower height at the central portions disposed in the respective emission areas EA, and may have a higher height by the patterns arranged thereunder in the non-emission area NEA around the emission areas EA. For example, the edge portion of each of the color filters CF of the second pixel PX2 may be disposed at least on the first light blocking layer BM1 in the non-emission area NEA, and thus may protrude more upward than the central portion disposed in the emission area EA. For example, each of the color filters CF of the second pixel PX2 may have a concave shape having a lower height in the emission area EA. In one embodiment, each of the color filters CF of the second pixel PX2 may have a thickness that is set according to the light emission efficiency of the light emitting element ED or the like regardless of whether or not the second pattern PTN2 is disposed at the central portion disposed in the emission area EA. For example, the central portions of the first color filter CF1, the second color filter CF2, and the third color filter CF3 of the second pixel PX2 may have the first thickness d1, the second thickness d2, and the third thickness d3, respectively. Accordingly, the front light emission ratio of the pixels PX may be uniform overall. For example, the front light emission ratios of the first pixel PX1 and the second pixel PX2 may be substantially the same or similar.

In one embodiment, the second pattern PTN2 may be entirely disposed in the non-emission area NEA of the second pixel PX2. For example, as illustrated in FIG. 13, the second pattern PTN2 may be entirely disposed in the non-emission area NEA of the second pixel PX2 to surround the first emission area EA1, the second emission area EA2, and the third emission area EA3 of the second pixel PX2.

In another embodiment, the second pattern PTN2 may be partially disposed in the non-emission area NEA of the second pixel PX2, and may surround only some emission areas EA among the emission areas EA of the second pixel PX2. For example, the second pattern PTN2 may be disposed only around the emission area EA that emits light of a specific color (e.g., first color light, second color light, or third color light) among the emission areas EA of the second pixel PX2. For example, as illustrated in FIG. 14, the second pattern PTN2 may be partially disposed in the non-emission area NEA of the second pixel PX2, and may selectively surround only the second emission area EA2 of the second pixel PX2. Alternatively, the second pattern PTN2 may surround the plurality of emission areas EA that emit light of different colors among the emission areas EA of the second pixel PX2, and may not surround the other emission areas EA.

In one embodiment, the second pattern PTN2 may be disposed only in a part of the second pixel area where the second pixel PX2 is disposed. For example, the second pattern PTN2 may be partially or entirely disposed in the non-emission area NEA of the second pixel PX2, and may not be disposed in the emission areas EA of the second pixel PX2.

Among the color filters CF of the second pixel PX2, at least one color filter CF disposed on the second pattern PTN2 may have a surface contour similar to that of the second pattern PTN2. For example, at least one color filter CF disposed on the second pattern PTN2 may protrude to a higher height at the edge portion by the second pattern PTN2. Accordingly, the stepped portion between the center portion and the edge portion of the color filter CF disposed on the second pattern PTN2 may increase due to the second pattern PTN2.

Since the stepped portion between the center portion and the edge portion of at least one of the color filters CF of the second pixel PX2 is increased by the second pattern PTN2, the side light emitted from the emission area EA surrounded by the second pattern PTN2 may be reduced. For example, compared to the second pixel PX2 of FIG. 10 that does not include the second pattern PTN2 in the second pixels PX2 of FIGS. 13 and 14, the color filter transmission length (e.g., a color filter transmission length L4′ of the second side light Ls2) of at least a part of the side light (e.g., the second side light Ls2) may increase or maximize. Accordingly, the amount of side light emitted from the second pixel PX2 may be reduced, thereby more effectively restricting the light exit angle, the side luminance, or the side viewing angle of the second pixel PX2.

In one embodiment, at least one emission area EA that has a greater influence on the side luminance or the side color of the second pixel PX2 may be selected, and the second pattern PTN2 may be selectively disposed only around the at least one emission area EA. For example, depending on the colors of light emitted from the respective emission areas EA or the sizes of the emission areas EA, the second pattern PTN2 may be selectively disposed only around some emission areas EA including at least one emission area EA that has a greater influence on the side luminance or the side color. In terms of an emission color, when the first color light, the second color light, and the third color light emitted from the first emission area EA1, the second emission area EA2, and the third emission area EA3 of the second pixel PX2 are red light, green light, and blue light, respectively, the second pattern PTN2 may be disposed at least around the second emission area EA2 of the second pixel PX2. In terms of a light emitting area, when the size of the second emission area EA2 among the first emission area EA1, the second emission area EA2, and the third emission area EA3 of the second pixel PX2 is smallest, the second pattern PTN2 may be disposed at least around the second emission area EA2 of the second pixel PX2. Accordingly, the color filter transmission length LA′ of the second side light Ls2 of the second color emitted from the second pixel PX2 may increase, so that the luminance of the second side light Ls2 of the second color may decrease.

The amount of side light emitted from the emission area EA that is not surrounded by the second pattern PTN2 may not be considerably changed by the second pattern PTN2. For example, when the second pattern PTN2 is partially disposed only around the second emission area EA2 of the second pixel PX2, the luminances of the first color side light and the third color side light of the second pixel PX2 may be substantially the same as or similar to those in the embodiment of FIG. 10.

By reducing the side light of a specific color emitted from the second pixel PX2, for example, the second side light Ls2 of the second color, the side luminance and/or side color of the second pixel PX2 may be adjusted (or corrected) or improved. For example, by reducing or minimizing the second side light Ls2 of the green color, which has the greatest influence on the side luminance and/or side color of the second pixel PX2, the side light blocking rate of the second pixel PX2 may further increase, and the viewing angle restriction effect may be enhanced in the second emission mode in which the side viewing angle is limited.

In one embodiment, the second pattern PTN2 may be disposed only around some emission areas EA among the emission areas EA of the second pixels PX2 to reduce or minimize the side color difference between the first pixels PX1 and the second pixels PX2. For example, in the first emission mode in which both the first pixels PX1 and the second pixels PX2 are driven, the second pattern PTN2 may be partially disposed in the non-emission area NEA of each of the second pixels PX2 to reduce the side color difference between the first pixels PX1 and the second pixels PX2. For example, in FIG. 14, the second pattern PTN2 is disposed only around the second emission area EA2 in the non-emission area NEA of the second pixel PX2, but the position or size of the second pattern PTN2 may vary. By reducing or minimizing the side color difference between the first pixels PX1 and the second pixels PX2, it is possible to prevent stains of a pixel unit from being visually recognized in the first emission mode.

According to the embodiments of FIGS. 13 and 14, the side light emitted from the second pixels PX2 may be more effectively reduced or blocked by the second pattern PTN2. Therefore, the viewing angle restriction effect in the second emission mode may be enhanced.

In some embodiments, by selectively disposing the second pattern PTN2 only around at least one emission area EA among the emission areas EA of the second pixels PX2, the side luminance and/or side color of the second pixels PX2 may be appropriately adjusted or improved. For example, the side luminance and/or side color of the second pixels PX2 may be adjusted to reduce or minimize the side color difference between the first pixels PX1 and the second pixels PX2. Accordingly, the image quality of the display device 10 may be improved.

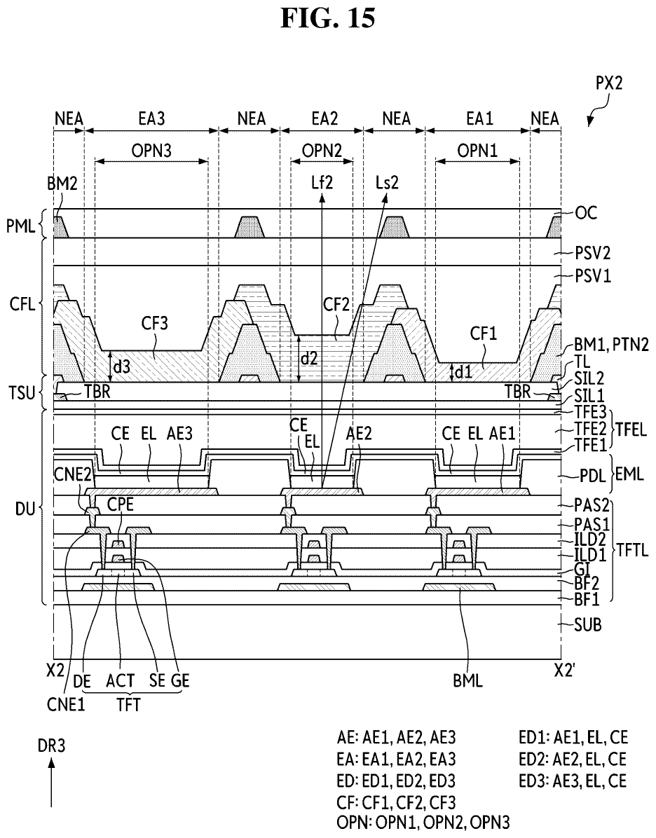

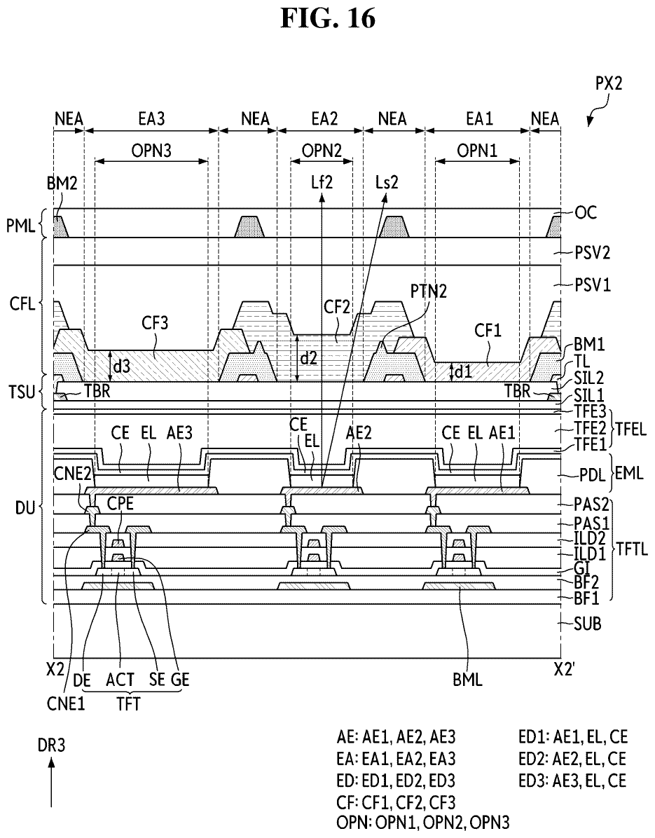

FIG. 15 is a cross-sectional view illustrating a display device according to one embodiment. FIG. 16 is a cross-sectional view showing a display device according to one embodiment. For example, FIG. 15 and FIG. 16, which show different embodiments of a part of the display device 10 corresponding to the cross section of the second pixel PX2 along line X2-X2′ of FIG. 4 to FIG. 8, show embodiments different from the embodiments of FIG. 13 and FIG. 14 in relation to the first light blocking layer BM1 and the second pattern PTN2.

Referring to FIG. 15 and FIG. 16, the first light blocking layer BM1 and the second pattern PTN2 may be formed in one piece. For example, the first light blocking layer BM1 and the second pattern PTN2 may be formed by a single mask process using a half-tone mask. In this case, the second pattern PTN2 may include a light blocking material, and may be considered as a part of the first light blocking layer BM1. For example, by forming the first light blocking layer BM1 protruding upward at a position where the increased height of the color filter CF is required, the first light blocking layer BM1 may function as the second pattern PTN1. Since the first light blocking layer BM1 and the second pattern PTN2 are formed simultaneously and/or integrally, the manufacturing process of the display device 10 may be simplified.

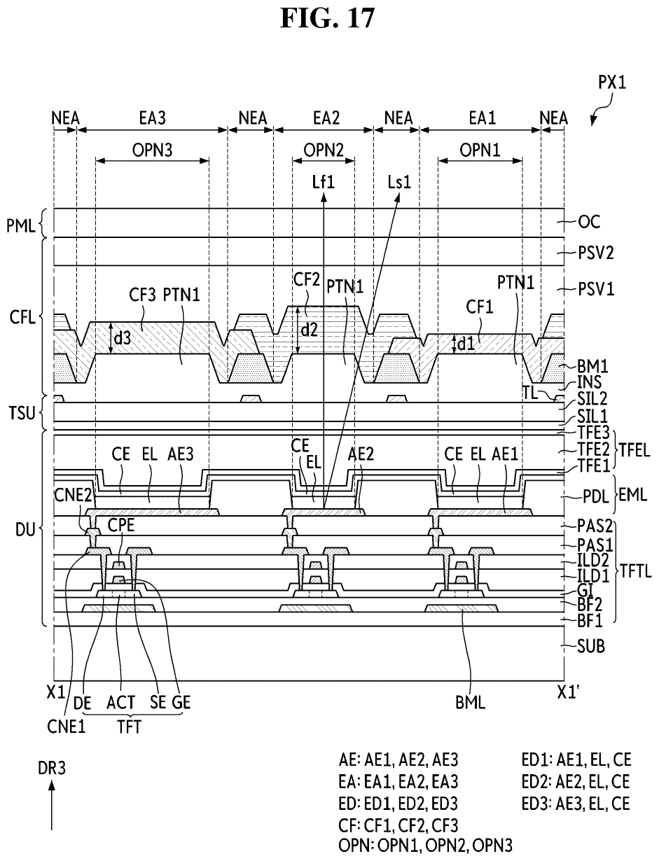

FIG. 17 is a cross-sectional view showing a display device according to one embodiment. For example, FIG. 17, which shows a part of the display device 10 corresponding to the cross section of the first pixel PX1 along line X1-X1′ of FIGS. 4 to 8, shows an embodiment different from the embodiments of FIGS. 11 and 12 in relation to the first pattern PTN1.

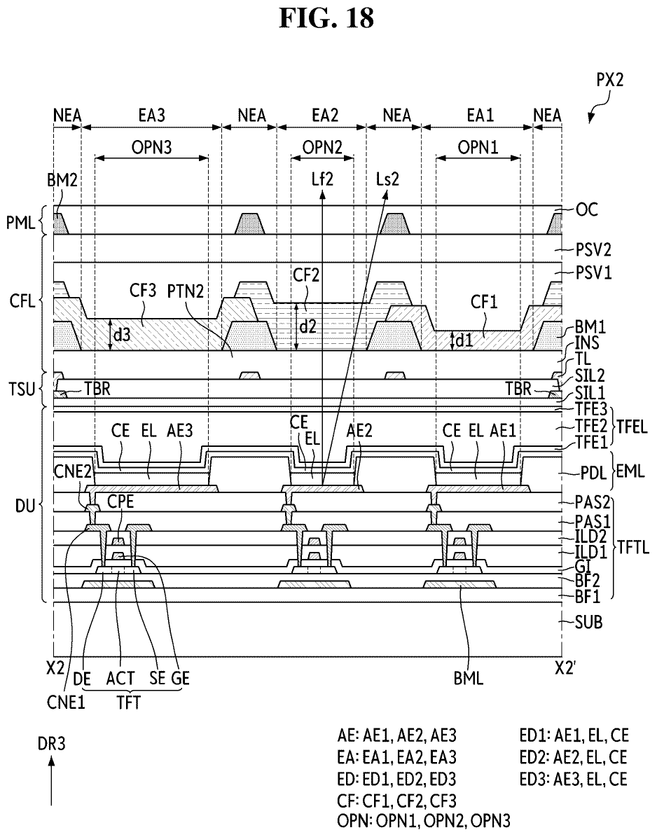

FIG. 18 is a cross-sectional view showing a display device according to one embodiment. For example, FIG. 18, which shows a part of the display device 10 corresponding to the cross section of the second pixel PX2 along line X2-X2′ of FIGS. 4 to 8, shows an embodiment different from the embodiments of FIGS. 13 to 16 in relation to the second pattern PTN2.

Referring to FIGS. 17 and 18, the display device 10 may further include an insulating layer INS covering the touch electrode TL, and the first pattern PTN1 and the second pattern PTN2 may be formed integrally with the insulating layer INS. In one embodiment, the insulating layer INS may be entirely formed in the display area DA. For example, the insulating layer INS may entirely cover the touch sensing layer TSU including the touch electrode TL.

The insulating layer INS may have a light transmitting property. For example, the insulating layer INS may be substantially transparent. Accordingly, light emitted from the light emitting elements ED may transmit through the insulating layer INS.

The insulating layer INS may partially protrude upward from at least one emission area EA among the emission areas EA of the first pixel PX1. For example, the top surface of the insulating layer INS in the first pixel area may have a stepped portion. Accordingly, the insulating layer INS may form each first pattern PTN1 at a position corresponding to the at least one emission area EA. Accordingly, the side luminance and/or side color of the first pixel PX1 may be improved.

In one embodiment, the insulating layer INS may be entirely disposed in the second pixel area including the emission areas EA of the second pixel PX2 and the non-emission area NEA around the emission areas EA. In one embodiment, the insulating layer INS may have a substantially uniform thickness in the emission areas EA and the non-emission area NEA of the second pixel PX2, and the top surface of the insulating layer INS may be substantially flat in the second pixel area. Accordingly, in the second pixel area, regardless of whether or not the second pattern PTN2 is disposed, the color filters CF may have a shape according to the first light blocking layer BM1 or the like, and the side luminance or side color of the second pixel PX2 may be substantially unchanged. However, the embodiments are not limited thereto. For example, in another embodiment, the thickness of the insulating layer INS may be differentiated for each part also in the second pixel area. For example, the thickness of the insulating layer INS may be differentiated for each part such that the thickness of the insulating layer INS is partially increased around at least one emission area EA among the emission areas EA of the second pixel PX2 or the thickness of the insulating layer INS is partially decreased in the at least one emission area EA to reduce the side light emitted from the at least one emission area EA. Accordingly, the side luminance and/or side color of the second pixel PX2 may be adjusted or optimized.

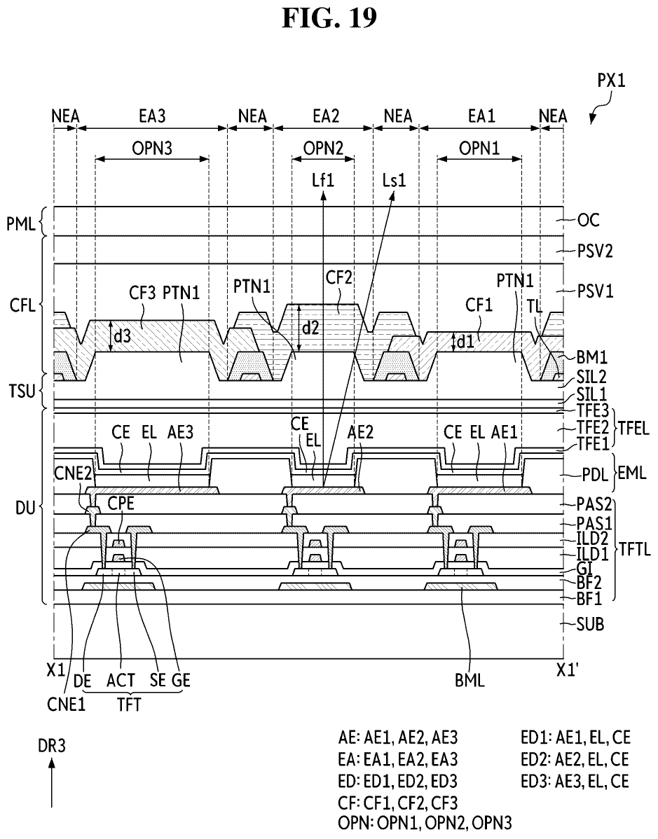

FIG. 19 is a cross-sectional view illustrating a display device according to one embodiment. For example, FIG. 19, which shows a part of the display device 10 corresponding to the cross section of the first pixel PX1 along line X1-X1′ of FIGS. 4 to 8, shows an embodiment different from the embodiments of FIGS. 11, 12, and 17 in relation to the first pattern PTN1.

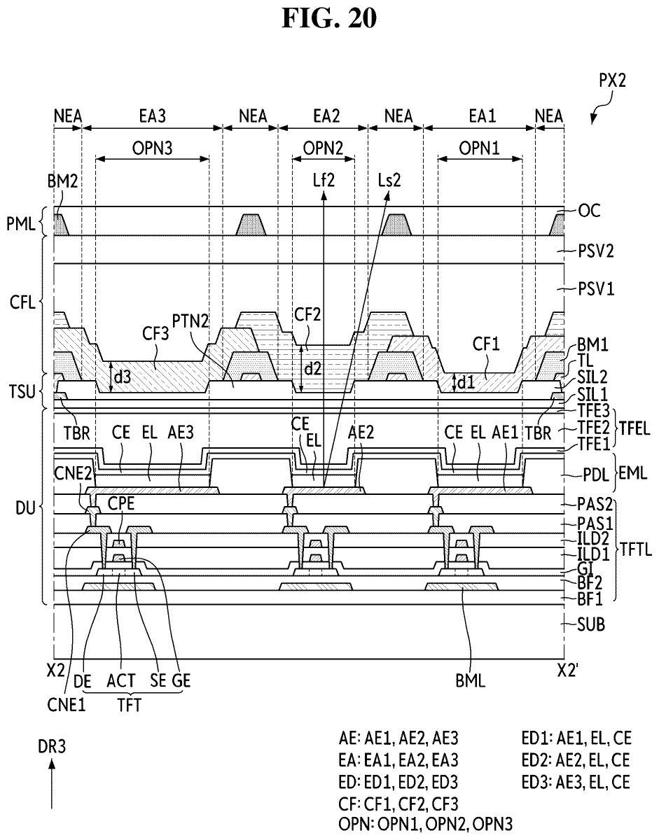

FIG. 20 is a cross-sectional view showing a display device according to one embodiment. For example, FIG. 20, which shows a part of the display device 10 corresponding to the cross section of the second pixel PX2 along line X2-X2′ of FIGS. 4 to 8, shows an embodiment different from the embodiments of FIGS. 13, 14, 15, 16, and 18 in relation to the second pattern PTN2.

Referring to FIGS. 19 and 20, the first pattern PTN1 and the second pattern PTN2 may be arranged between the light emitting element layer EML and the color filter layer CFL. For example, the first pattern PTN1 and the second pattern PTN2 may be arranged in the touch sensing layer TSU.

In one embodiment, the first pattern PTN1 and the second pattern PTN2 may be formed integrally with an insulating layer disposed under the touch electrode TL. For example, the first pattern PTN1 and the second pattern PTN2 may be formed integrally with the second insulating layer SIL2 of the touch sensing layer TSU.

In one embodiment, the second insulating layer SIL2 may partially protrude in at least one emission area EA among the emission areas EA of the first pixel PX1. Accordingly, the second insulating layer SIL2 may form each first pattern PTN1 at a position corresponding to the at least one emission area EA. Accordingly, the side luminance and/or side color of the first pixel PX1 may be improved.

In one embodiment, the second insulating layer SIL2 may have partially different thicknesses and/or heights in the second pixel area. For example, the second insulating layer SIL2 may have a relatively large thickness and protrude upward in the non-emission area NEA around at least one emission area EA among the emission areas EA of the second pixel PX2, and may have a relatively small thickness and have a downwardly recessed shape in the emission areas EA of the second pixel PX2. Accordingly, the color filter transmission length of the side light emitted from at least one emission area EA among the emission areas EA of the second pixel PX2 may increase, so that the side light emitted from the at least one emission area EA may be reduced. Accordingly, the side luminance and/or side color of the second pixel PX2 may be adjusted or optimized by the second pattern PTN2.

However, the embodiments are not limited thereto. For example, in another embodiment, the second insulating layer SIL2 may have an overall uniform thickness in the second pixel area. Accordingly, in the second pixel area, regardless of whether or not the second pattern PTN2 is disposed, the color filters CF may have a shape according to the first light blocking layer BM1 or the like, and the side luminance or side color of the second pixel PX2 may be substantially unchanged.

As described above, according to embodiments, the viewing angle of the display device 10 may be altered depending on emission modes selected by a user by utilizing the first pixels PX1 and the second pixels PX2 having different light exit angles or viewing angles. For example, by selectively arranging the first light blocking layer BM1 and the second light blocking layer BM2 in the first pixels PX1 and the second pixels PX2 arranged in the display area DA, the light exit angles or the side viewing angles of the first pixels PX1 and the second pixels PX2 may be differentiated or optimized, and the first pixels PX1 and the second pixels PX2 may be selectively driven according to the selected emission mode. Accordingly, the side viewing angle of the image displayed in the display area DA may be appropriately and/or easily altered in response to the selected emission mode by the user.

Further, according to embodiments, by utilizing at least one of the first pattern PTN1 or the second pattern PTN2, the side light emission ratio of the first pixels PX1 and the second pixels PX2 may be further differentiated or optimized, and the side luminance and/or side color of the display device 10 may be improved. For example, by disposing the first pattern PTN1 under at least one color filter CF among the color filters CF arranged in the emission areas EA of the first pixels PX1, at least one color filter CF may be formed to have a shape protruding in the height direction at least in the emission area EA. For example, at least one of the color filters CF of the first pixels PX1 may have a convex cross-sectional shape. Accordingly, the side light emission ratio of the first pixels PX1 may be increased, and the luminance and the viewing angle of the first pixels PX1 may be improved.

In some embodiments, the first pattern PTN1 may be selectively disposed only in some emission areas EA among the emission areas EA of the first pixels PX1 to prevent or reduce the viewing angle color shift. Accordingly, the viewing angle color shift may be prevented or reduced in the first emission mode in which the first pixels PX are driven and a wider viewing angle is provided, and the side color of the display device 10 may be adjusted or improved.

In addition, according to some embodiments, by disposing the second pattern PTN2 under the edge of at least one color filter CF among the color filters CF arranged in the emission areas EA of the second pixels PX2, the at least one color filter CF may be formed to have a shape protruding more in the height direction in the non-emission area NEA around the emission area EA. For example, the second pattern PTN2 may be disposed partially or entirely in the non-emission area NEA of each of the second pixels PX2. Accordingly, at least one of the color filters CF of each of the second pixels PX2 may have a concave cross-sectional shape in which the stepped portion between the central portion and the edge portion is further increased. Accordingly, the side viewing angle may be more effectively limited in the second emission mode in which the side light of the second pixels PX2 is reduced or blocked, and the viewing angle is limited by displaying an image only by the second pixels PX2.

In some embodiments, the second pattern PTN2 may be selectively arranged only in the non-emission area NEA around some emission areas EA among the emission areas EA of the second pixels PX2 to prevent or reduce the viewing angle color shift. In some embodiments, by controlling the side light of the first pixels PX1 and the second pixels PX2 by utilizing at least one of the first pattern PTN1 or the second pattern PTN2, the side color difference between the first pixels PX1 and the second pixels PX2 may be reduced or prevented. For example, when the side color of the second pixel PX2 becomes reddish compared to the side color of the first pixel PX1, the ratio of red light in the side light emitted from the second pixel PX2 may be reduced by forming the first color filter CF1 of the second pixel PX2 in a concave shape in which the stepped portion between the central portion and the edge portion is further increased using the second pattern PTN2. Further, the ratio of red light in the side light emitted from the first pixel PX1 may increase by forming the first color filter CF1 of the first pixel PX1 in a convex shape using the first pattern PTN1 and/or forming or maintaining the second color filter CF2 of the first pixel PX1 in a concave shape. Alternatively, only the side color of the second pixel PX2 may be adjusted by the second pattern PTN2 without changing the side color of the first pixel PX1, or only the side color of the first pixel PX1 may be adjusted by the first pattern PTN1 without changing the side color of the second pixel PX2. Accordingly, the side color difference between the first pixels PX1 and the second pixels PX2 may be reduced or minimized, and the image quality of the display device 10 may be improved.

The first pattern PTN1 and the second pattern PTN2 according to embodiments may be independently applied to the first pixel PX1 and the second pixel PX2, respectively, and all possible combinations of embodiments may fall within the scope of the present disclosure. For example, each embodiment may be applied alone to the display device 10, or at least two embodiments according to possible combinations among the embodiments may be applied together to the display device 10. For example, the display device 10 including the first pixel PX1 and the second pixel PX2 may include the first pattern PTN1 disposed in each of the first pixels PX1 and may not include the second pattern PTN2, may include the second pattern PTN2 disposed in each of the second pixels PX2 and may not include the first pattern PTN1, or may include both the first pattern PTN1 disposed in each of the first pixels PX1 and the second pattern PTN2 disposed in each of the second pixels PX2.

In concluding the detailed description, those skilled in the art will appreciate that many variations and modifications can be made to the embodiments without substantially departing from the principles of the present inventive concept. Therefore, the disclosed embodiments of the inventive concept are used in a generic and descriptive sense only and not for purposes of limitation.

What is claimed is:

1. A display device comprising:
a display area comprising emission areas and a non-emission area surrounding the emission areas, the emission areas including emission areas of a first pixel and emission areas of a second pixel;
a light emitting element layer comprising light emitting elements arranged in the emission areas;
a color filter layer disposed on the light emitting element layer and comprising color filters respectively arranged in the emission areas;
a first light blocking layer disposed in the non-emission area on the light emitting element layer;
a first pattern disposed between the light emitting element layer and the color filter layer, and disposed under at least one color filter of the first pixel; and
a second light blocking layer disposed on the color filter layer and surrounding the emission areas of the second pixel,
wherein the at least one color filter of the first pixel comprises a central portion that is disposed on the first pattern and protrudes in a height direction, and an edge portion that surrounds the central portion and has a lower height than the central portion.

2. The display device of claim 1, wherein the emission areas of the first pixel comprise a first emission area emitting light of a first color, a second emission area emitting light of a second color, and a third emission area emitting light of a third color.

3. The display device of claim 2, wherein the light of the first color, the light of the second color and the light of the third color are red light, green light and blue light, respectively.

4. The display device of claim 3, wherein the first pattern is disposed in at least the second emission area.

5. The display device of claim 2, wherein a size of the second emission area is smaller than a size of each of the first emission area and the third emission area.

6. The display device of claim 5, wherein the first pattern is disposed in at least the second emission area.

7. The display device of claim 2, wherein the first pattern is individually disposed in each of the first emission area, the second emission area, and the third emission area.

8. The display device of claim 2, wherein the first pattern is disposed in at least two of the first emission area, the second emission area, and the third emission area.

9. The display device of claim 8, wherein a color filter disposed in an emission area where the first pattern is not disposed comprises a central portion disposed in the emission area where the first pattern is not disposed, and an edge portion surrounding the central portion and having a height higher than that of the central portion.

10. The display device of claim 1, wherein the first pattern is formed as a light transmitting pattern.

11. The display device of claim 10, further comprising a touch electrode disposed between the light emitting element layer and the color filter layer.

12. The display device of claim 11, further comprising an insulating layer covering the touch electrode or disposed under the touch electrode and formed integral with the first pattern,
wherein the insulating layer partially protrudes from a first pixel area to form the first pattern.

13. The display device of claim 1, further comprising a second pattern disposed between the light emitting element layer and the color filter layer, and disposed under at least one color filter in the non-emission area surrounding an emission area of the second pixel.

14. The display device of claim 13, wherein the at least one color filter disposed on the second pattern has a higher height at an edge portion disposed on the second pattern than at a central portion disposed in a corresponding emission area.

15. The display device of claim 13, wherein the second pattern is disposed under the first light blocking layer and overlaps the first light blocking layer.

16. The display device of claim 13, wherein the second pattern and the first light blocking layer are integral with each other.

17. The display device of claim 13, wherein the second pattern is disposed only in the non-emission area of the second pixel and is not disposed in the emission areas of the second pixel.

18. The display device of claim 13, wherein the second pattern is disposed entirely in a second pixel area comprising the emission areas of the second pixel and the non-emission area of the second pixel.

19. The display device of claim 13, further comprising:
a touch electrode disposed between the light emitting element layer and the color filter layer; and
an insulating layer covering the touch electrode or disposed under the touch electrode and integral with the second pattern.

20. An electronic device including a display device, the display device comprising:
a display area comprising emission areas and a non-emission area surrounding the emission areas, the emission area including emission areas of a first pixel and emission areas of a second pixel;
a light emitting element layer comprising light emitting elements arranged in the emission areas;
a color filter layer disposed on the light emitting element layer and comprising color filters respectively arranged in the emission areas;
a first light blocking layer disposed in the non-emission area;
a first pattern disposed between the light emitting element layer and the color filter layer, and disposed under at least one color filter of the first pixel; and
a second light blocking layer disposed on the color filter layer, and surrounding emission areas of the second pixel,
wherein the at least one color filter of the first pixel comprises a central portion that is disposed on the first pattern and protrudes in a height direction, and an edge portion that
surrounds the central portion and has a lower height than the central portion.
